(19) United States
(12) Patent Application Publication
(10) Pub. No.: US 2026/0088107 A1
(43) Pub. Date: Mar. 26, 2026

(54) SEMICONDUCTOR DEVICE

(71) Applicant: Kioxia Corporation, Tokyo (JP)

(72) Inventor: Tomohiko ITO, Kawasaki (JP)

(73) Assignee: Kioxia Corporation, Tokyo (JP)

(21) Appl. No.: 19/078,539

(22) Filed: Mar. 13, 2025

(30) Foreign Application Priority Data
Sep. 20, 2024 (JP) 2024-163829

(51) Int. Cl. G11C 16/30; G11C 16/04

(52) U.S. Cl. CPC G11C 16/30; G11C 16/0483

(57) ABSTRACT

A conductor device includes a first power line to which a first voltage is supplied, a second power line to which a second voltage lower than the first voltage is supplied, a first logic circuit including a first electrode, and electrically connected to the first power line, a second logic circuit including a second electrode provided separately from the first electrode, and electrically connected to the first power line and the first logic circuit, a voltage supplying circuit that controls, based on a first control signal, whether or not to supply a third voltage to the first electrode, the third voltage being lower than the first voltage and higher than the second voltage, and a first transistor including a gate electrode to which a second control signal is input, and electrically connected between the second electrode and the second power line.

### CROSS-REFERENCE TO RELATED APPLICATION

This application is based upon and claims the benefit of priority from Japanese Patent Application No. 2024-163829, filed Sep. 20, 2024, the entire contents of which are incorporated herein by reference.

### FIELD

Embodiments described herein relate generally to a semiconductor device.

### BACKGROUND

A memory system including a NAND flash memory as a semiconductor device is known.

### BRIEF DESCRIPTION OF THE DRAWINGS

FIG. 1 is a block diagram illustrating the configurations of a memory system including a semiconductor memory device according to a first embodiment and a host.

FIG. 2 is a block diagram illustrating the configuration of the memory system including the semiconductor memory device according to the first embodiment.

FIG. 3 is a circuit diagram illustrating the configuration of a memory cell according to the first embodiment.

FIG. 4 is a diagram illustrating an example of a sense amplifier module according to the first embodiment.

FIG. 5 is a diagram illustrating the configuration of a circuit for outputting data toward the memory cell array from an input/output circuit according to the first embodiment.

FIG. 6 is a circuit diagram illustrating the configuration of a leakage current reduction circuit according to the first embodiment.

FIG. 7 is a diagram illustrating the operation of the leakage current reduction circuit illustrated in FIG. 6.

FIG. 8 is a circuit diagram illustrating the configuration of a leakage current reduction circuit according to the first embodiment.

FIG. 9 is a circuit diagram illustrating an example of the configuration of a leakage current reduction circuit according to a comparison example.

FIG. 10 is a illustrating an n-channel MOS transistor and the electrical characteristics of the n-channel MOS transistor.

FIG. 11 is a diagram illustrating a p-channel MOS transistor and the electrical characteristics of the p-channel MOS transistor.

FIG. 12 is a schematic diagram illustrating examples of the structures of the n-channel MOS transistor and the p-channel MOS transistor.

FIG. 13 is a circuit diagram illustrating the configuration of a leakage current reduction circuit according to a second embodiment.

FIG. 14 is a diagram illustrating the operation of the leakage current reduction circuit illustrated in FIG. 13.

FIG. 15 is a diagram illustrating the operation of the leakage current reduction circuit illustrated in FIG. 13.

### DETAILED DESCRIPTION

A semiconductor device capable of suppressing a leakage current is provided.

In general, according to one embodiment, a semiconductor memory device includes a first power line to which a first voltage is supplied, a second power line to which a second voltage lower than the first voltage is supplied, a first logic circuit including a first electrode, and electrically connected to the first power line, a second logic circuit including a second electrode provided separately from the first electrode, and electrically connected to the first power line and the first logic circuit, a voltage supplying circuit that controls, based on a first control signal, whether or not to supply a third voltage to the first electrode, the third voltage being lower than the first voltage and higher than the second voltage, and a first transistor including a gate electrode to which a second control signal is input, and electrically connected between the second electrode and the second power line.

According to another embodiment, a semiconductor memory device includes a first power line to which a first voltage is supplied, a second power line to which a second voltage lower than the first voltage is supplied, a first logic circuit including a first electrode, and electrically connected to the first power line, a second logic circuit including a second electrode provided separately from the first electrode, and electrically connected to the first power line and the first logic circuit, a voltage supplying circuit that controls, based on a first control signal, whether or not to supply a third voltage to the first electrode, the third voltage being lower than the first voltage and higher than the second voltage, a first transistor including a gate electrode to which a second control signal is input, and electrically connected between the second electrode and the second power line, a second transistor including a gate electrode to which a third control signal is input, and electrically connected between the first electrode and the second power line, a first switch, switching of which is controlled by a fourth control signal, and which is electrically connected between the voltage supplying circuit and the first electrode, and a second switch, switching of which is controlled by the fourth control signal, and which is electrically connected between the voltage supplying circuit and the second electrode.

Hereinafter, each embodiment will be described with reference to the drawings. Note that, in the following description, components having the same or similar functions and configurations are given common reference numerals. When distinguishing between a plurality of components having a common reference numeral, the components are distinguished by adding subscripts (for example, uppercase letters of the alphabet, lowercase letters of the alphabet, numbers, hyphens and uppercase letters and numbers, or the like) to the common reference numeral.

In the following description, a signal X<p:0> (p is a natural number) is a (p+1)-bit signal, and means a set of signals X<0>, X<1>, . . . , X<p>, each of which is a 1-bit signal. A component Y<p:0> means a set of components Y<0>, Y<1>, . . . Y<P> that correspond one-to-one to inputs or outputs of the signal X<p:0>.

### 1. First Embodiment

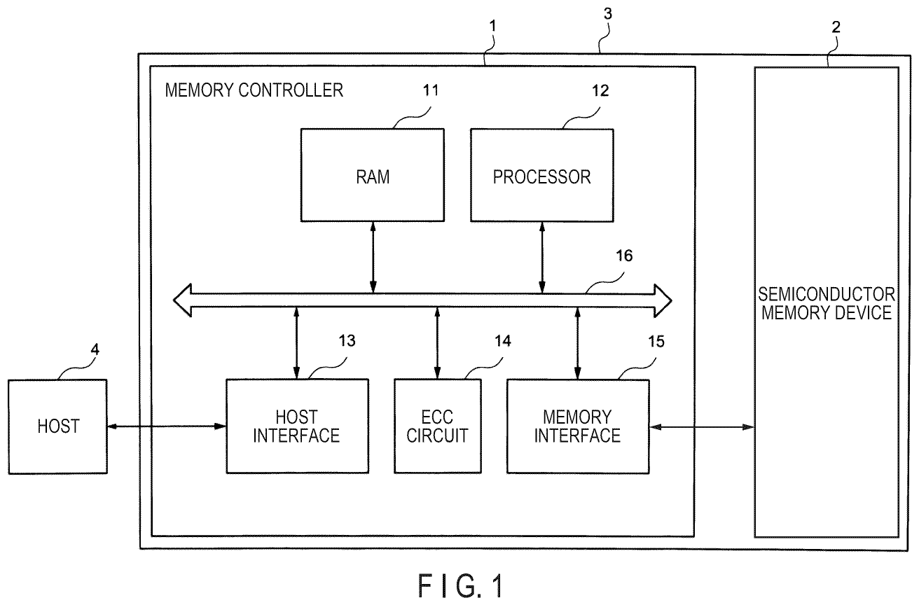

Referring to FIG. 1 to FIG. 8, a semiconductor device according to a first embodiment will be described. As an example, the semiconductor device is a memory system 3.

### 1-1. Summary of Memory System 3 and Host 4

Referring to FIG. 1, the summary of the memory system 3 and a host 4 will be described. FIG. 1 is a block diagram illustrating configuration examples of the memory system 3 and the host 4. The memory system 3 includes a memory controller 1 and a semiconductor memory device 2. The memory system 3 can be connected to the host 4. The memory system 3 is, for example, a memory card or the like, such as an SSD (solid state drive) and an SDTM card. The host 4 is, for example, an electronic device, such as a personal computer and a mobile terminal. The memory system 3 may include the host 4.

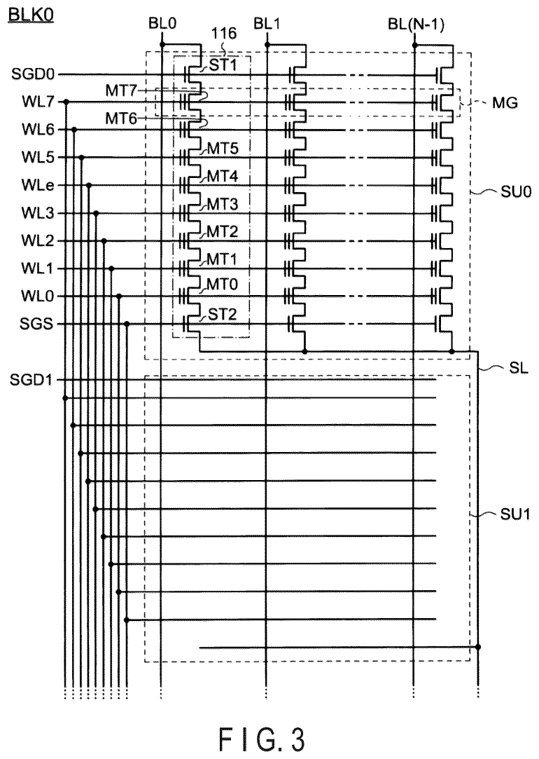

The semiconductor memory device 2 is connected to, for example, the memory controller 1, and is controlled by using the memory controller 1. The semiconductor memory device 2 is a memory that stores data in a non-volatile manner, and includes, for example, a NAND memory (NAND flash memory). The semiconductor memory device 2 includes i memory cells electrically connected i bit lines BL. Each of the memory cells includes a memory cell transistor MT (refer to FIG. 3). One memory cell (memory cell transistor MT) can be set to 2n or more kinds of threshold voltages (n is a positive integer). In this case, a plurality of memory cells, which are the units of read operation and write operation, can hold data for n pages. For example, when the unit of data that is the subject of a read operation and a write operation is 16 kB, the read operation and write operation are collectively performed on 217 memory cells.

The semiconductor memory device 2 may include a 5-bit/Cell ((PLC) Penta Level Cell) NAND memory having memory cells that can be set to a 5-bit (25 kinds, 32 values) threshold voltage per memory cell. In addition, the semiconductor memory device 2 may include a 4-bit/Cell (QLC (Quad Level Cell)) NAND memory having memory cells that can be set to a 4-bit (24 kinds, 16 values) threshold voltage per memory cell, may include a 3-bit/Cell (TLC (Triple Level Cell)) NAND memory having memory cells that can be set to a 3-bit (23 kinds, 8 values) threshold voltage per memory cell, or may include a 2-bit/Cell (MLC (Multi Level Cell)) NAND memory having memory cells that can be set to a 2-bit (22 kinds, 4 values) threshold voltage per memory cell. For example, when the semiconductor memory device 2 includes the 5-bit/Cell NAND memory, 217 memory cells as the unit of read operation and write operation can hold data for 5 pages (16 kB×5).

For example, the memory controller 1 receives a request required for the operation of the semiconductor memory device 2 from the host 4, and transmits the request to the semiconductor memory device 2. The memory controller 1 transmits the request to the semiconductor memory device 2, and controls a read operation of data from the semiconductor memory device 2, a write operation of data to the semiconductor memory device 2, and an erase operation of data of the semiconductor memory device 2.

### 1-2. Configuration of Memory Controller 1

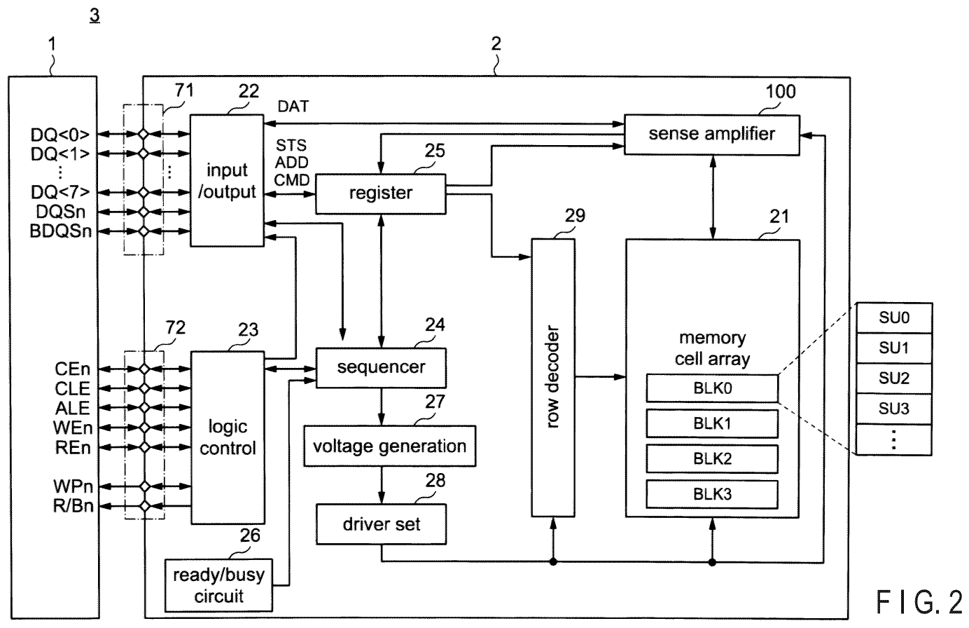

Referring to FIG. 1 and FIG. 2, the configuration of the memory controller 1 will be described. FIG. 2 is a block diagram illustrating the configuration of the memory system 3 including the semiconductor memory device 2.

Each of signals, i.e., a chip enable signal CEn, a command latch enable signal CLE, an address latch enable signal ALE, a write enable signal WEn, a read enable signal REn, a write protect signal WPn, a signal DQ<7:0>, a data strobe signal DQSn, and a complementary signal BDQSn of the data strobe signal DQSn, is transmitted and received between the memory controller 1 and the semiconductor memory device 2.

For example, each the semiconductor memory device 2 and the memory controller 1 is formed as a semiconductor chip (hereinafter also simply referred to as a chip).

The chip enable signal CEn is a signal for enabling (activating) the semiconductor memory device 2. The command latch enable signal CLE is a signal for notifying an input/output circuit 22 that the signal DQ input to the semiconductor memory device 2 is a command CMD. The address latch enable signal ALE is a signal for notifying the input/output circuit 22 that the signal DQ input to the semiconductor memory device 2 is address information ADD.

The write enable signal WEn is a signal for capturing the received signal into the semiconductor memory device 2, and is asserted whenever the memory controller 1 receives a command, an address, and data. For example, the write enable signal WEn instructs the semiconductor memory device 2 to capture the signal DQ <7:0> while the signal WEn is at a low level. Note that the write enable signal WEn may instruct the semiconductor memory device 2 to capture the signal DQ <7:0> while the signal WEn is at a high level. The low level may be written as the Low level, the “L” level, or “0,” and the high level may be written as the High level, the “H” level, or “1.” For example, the high level indicates a voltage having a high voltage value, the low level indicates a voltage having a low voltage value, and the high level is a higher voltage than the low level.

The read enable signal REn is a signal for the memory controller 1 to read data from the semiconductor memory device 2. For example, the read enable signal REn is used to control the operation timing of the semiconductor memory device 2 at the time of outputting the signal DQ <7:0>.

The write protect signal WPn is a signal for instructing the semiconductor memory device 2 to prohibit writing and erasing of data. The signal DQ <7:0> is the entity of data transmitted and received between the semiconductor memory device 2 and the memory controller 1. The signal DQ <7:0> is an 8-bit signal. The data strobe signal DQSn and the complementary signal BDQSn of the data strobe signal DQSn are signals for controlling the timing of input and output of the signal DQ <7:0>.

The memory controller 1 includes a RAM (Random Access Memory) 11, a processor 12, a host interface 13, an ECC (Error Check and Correct) circuit 14, and a memory interface 15. The RAM 11, the processor 12, the host interface 13, the ECC circuit 14, and the memory interface 15 are connected to each other with an internal bus 16.

The host interface 13 outputs a request, user data (write data), and the like received from the host 4 to the internal bus 16. In addition, the host interface 13 transmits user data read from the semiconductor memory device 2, a response from the processor 12, and the like to the host 4.

The memory interface 15 controls a write operation that writes user data and the like to the semiconductor memory device 2, and a read operation that reads user data and the like from the semiconductor memory device 2, based on instructions from the processor 12.

The processor 12 generally controls the memory controller 1. The processor 12 is, for example, a CPU (Central Processing Unit), an MPU (Micro Processing Unit), or the like. When the processor 12 receives a request from the host 4 via the host interface 13, the processor 12 performs control according to the request. In some implementations, processor 12 may comprise circuitry or processing circuitry which includes general purpose processors, special purpose processors, integrated circuits, ASICs (“Application Specific Integrated Circuits”), FPGAs (“Field-Programmable Gate Arrays”), and/or combinations thereof which are programmed, using one or more programs stored in one or more memories, or otherwise configured to perform the disclosed functionality.

Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality.

The RAM 11 temporarily stores user data received from the host 4 until the user data is stored in the semiconductor memory device 2, and temporarily stores data read from the semiconductor memory device 2 until the data is transmitted to the host 4. The RAM 11 is, for example, a general-purpose memory, such as an SRAM (Static Random Access Memory) and a DRAM (Dynamic Random Access Memory).

The ECC circuit 14 encodes user data stored in the RAM 11 to generate a code word. In addition, the ECC circuit 14 decodes a code word read from the semiconductor memory device 2.

As an example, the memory system 3 indicated in FIG. 1 includes the memory controller 1 that includes the ECC circuit 14 and the memory interface 15. However, the memory system 3 is not limited to the example illustrated in FIG. 1. For example, the memory system 3 may include the ECC circuit 14 built in the memory interface 15, or may include the ECC circuit 14 built in the semiconductor memory device 2.

Here, the operation of the memory system 3 will be simply described.

For example, the processor 12 may instruct the memory interface 15 to perform a write operation of user data and parity to the semiconductor memory device 2, according to a request received from the host 4, and may instruct the memory interface 15 to perform a read operation of user data and parity from the semiconductor memory device 2, according to a request received from the host 4.

In addition, the processor 12 determines a storing region (memory region) on the semiconductor memory device 2 for user data stored in the RAM 11. User data is stored in the RAM 11 via the internal bus 16. The processor 12 performs the determination of a memory region for data in a unit of page (page data, for example, 16 kB), which is a write unit. For example, user data stored in one page of the semiconductor memory device 2 is defined as unit data. Generally, unit data is encoded by the ECC circuit 14 to be stored in the semiconductor memory device 2 as a code word. Encoding is not essential in the memory system 3. The memory controller 1 may store unit data in the semiconductor memory device 2 without encoding the unit data. Note that the configuration of the memory system 3 illustrated in FIG. 1 illustrates the configuration in which encoding is performed as a configuration example. When the memory controller 1 does not perform encoding, page data matches unit data. In addition, one code word may be generated based on one unit data, or one code word may be generated based on divided data obtained by dividing unit data. In addition, one code word may be generated by using a plurality of pieces of unit data.

In addition, the processor 12 determines a memory region of the semiconductor memory device 2 to which unit data is to be written for each unit data. A physical address is assigned to a memory region of the semiconductor memory device 2. The processor 12 manages the memory region to which unit data is to be written, by using the physical address. The processor 12 instructs the memory interface 15 to write the user data to the semiconductor memory device 2, by specifying the determined memory region (physical address). The processor 12 manages the correspondence between logical addresses (the logical addresses managed by the host 4) and physical addresses of user data. When the processor 12 receives a read request including a logical address from the host 4, the processor 12 specifies the physical address corresponding to the logical address, and instructs the memory interface 15 to perform reading of user data by specifying the physical address.

For example, when the memory system 3 receives a write request from the host 4, the memory system 3 is operated as follows. The processor 12 causes the RAM 11 to temporarily store data to be written. The processor 12 reads the data stored in the RAM 11, and inputs the data to the ECC circuit 14. The ECC circuit 14 encodes the input data, and inputs a code word to the memory interface 15. The memory interface 15 writes the input code word to the semiconductor memory device 2.

In addition, for example, when the memory system 3 receives a read request from the host 4, the memory system 3 is operated as follows. The memory interface 15 inputs, to the ECC circuit 14, the code word read from the semiconductor memory device 2. The ECC circuit 14 decodes the input code word, and stores the decoded data in the RAM 11. The processor 12 transmits the data stored in the RAM 11 to the host 4 via the host interface 13.

### 1-3. Configuration of Semiconductor Memory Device 2

Referring to FIG. 1 and FIG. 2, the configuration of the semiconductor memory device 2 will be described. As illustrated at FIG. 2, the semiconductor memory device 2 includes a memory cell array (memory cell array) 21, the input/output circuit (input/output) 22, a logic control circuit (logic control) 23, a sequencer (sequencer) 24, a register (register) 25, a ready/busy control circuit (ready/busy circuit) 26, a voltage generation circuit (voltage generation) 27, a driver set (driver set) 28, a row decoder (row decoder) 29, a sense amplifier module (sense amplifier) 100, an input/output pad group 71, and a logic control pad group 72. In the semiconductor memory device 2, various operations, such as a write operation that causes the memory cell array 21 to store write data DAT, and a read operation that reads read data DAT from the memory cell array 21, are performed.

The memory cell array 21 is connected to, for example, the sense amplifier module 100, the row decoder 29, and the driver set 28. The memory cell array 21 includes blocks BLK0, BLK1,. BLKn (n is an integer of one or more). Although details will be described later, each of the blocks BLK includes a plurality of string units SU (SU0, SU1, SU2, SU3).

Each of the string units SU includes a plurality of nonvolatile memory cells associated with a bit line and a word line. The blocks BLK serve as, for example, erasing units for data. The data held by memory cell transistors MTe0 to MTe7 and MTo0 to MTo7 (see FIG. 3) included in the same block BLK is collectively erased. Note that, in the semiconductor memory device 2, the memory cell transistor MT may be simply referred to as the memory cell.

The input/output circuit 22 is connected to, for example, the register 25, the logic control circuit 23, and the sense amplifier module 100. The input/output circuit 22 controls transmission and reception of the data signal DQ <7:0> between the memory interface 15 included in the memory controller 1 and the semiconductor memory device 2.

As described in “1-2. Configuration of Memory Controller 1,” the signal DQ <7:0> is the entity of the data transmitted and received between the semiconductor memory device 2 and the memory interface 15 included in the memory controller 1. The signal DQ <7:0> includes a command CMD, data DAT, address information ADD, status information STS, and the like.

The command CMD includes, for example, a command for executing a request transmitted to the semiconductor memory device 2 from the host 4 via the memory interface 15 included in the memory controller 1. The command CMD includes, for example, a command that instructs execution of a write request and a read request. The data DAT includes write data DAT to the semiconductor memory device 2, or read data DAT from the semiconductor memory device 2. The data DAT includes, for example, Edata. The address information ADD includes, for example, column addresses and row addresses for selecting a plurality of nonvolatile memory cells associated with bit lines and word lines. The status information STS includes, for example, information regarding the status of the semiconductor memory device 2 regarding a write operation and a read operation.

Specifically, the input/output circuit 22 includes an input circuit and an output circuit, and the input circuit and the output circuit perform processing described below. The input circuit receives write data DAT, address information ADD, and a command CMD from the memory controller 1. The input circuit transmits the received write data DAT to the sense amplifier module 100, and transmits the received address information ADD and command CMD to the register 25. On the other hand, the output circuit receives status information STS from the register 25, and receives read data DAT from the sense amplifier module 100. The output circuit transmits the received status information STS and read data DAT to the memory interface 15 included in the memory controller 1.

The logic control circuit 23 is connected to, for example, the memory controller 1 and the sequencer 24. The logic control circuit 23 receives, for example, the chip enable signal CEn, the command latch enable signal CLE, the address latch enable signal ALE, the write enable signal WEn, the read enable signal REn, and the write protect signal WPn via the memory interface 15 of the memory controller 1. The logic control circuit 23 controls the input/output circuit 22 and the sequencer 24 based on the received signals. The logic control circuit 23 and the sequencer 24 may be written as the “control circuit”, and any one of the logic control circuit 23 or the sequencer 24 may be written as the “control circuit.”

The sequencer 24 is connected to, for example, the ready/busy control circuit 26, the sense amplifier module 100, and the driver set 28. The sequencer 24 controls the operation of the entire semiconductor memory device 2 based on the command CMD held in a command register. For example, the sequencer 24 controls the sense amplifier module 100, the row decoder 29, the voltage generation circuit 27, the driver set 28, and the like to perform various operations, such as a write operation, a read operation, and an erase operation.

The register 25 includes, for example, a status register, an address register, a command register, and the like. The status register receives and holds the status information STS from the sequencer 24, and transmits the status information STS to the input/output circuit 22 based on an instruction from the sequencer 24. The address register receives and holds the address information ADD from the input/output circuit 22. The address register transmits a column address in the address information ADD to the sense amplifier module 100, and transmits a row address in the address information ADD to the row decoder 29. The command register receives and holds the command CMD from the input/output circuit 22, and transmits the command CMD to the sequencer 24.

The ready/busy control circuit 26 generates a ready/busy signal R/Bn according to control by the sequencer 24, and transmits the generated ready/busy signal R/Bn to the memory controller 1. The ready/busy signal R/Bn is a signal for notifying whether the semiconductor memory device 2 is in a ready state for receiving an instruction from the memory controller 1, or in a busy state for not receiving the instruction.

The voltage generation circuit 27 is connected to, for example, the driver set 28 and the like. The voltage generation circuit 27 generates the voltage to be used for a write operation, a read operation, and the like, based on control by the sequencer 24, and supplies the generated voltage to the driver set 28.

The driver set 28 is connected to the memory cell array 21, the sense amplifier module 100, and the row decoder 29. Based on the voltage supplied from the voltage generation circuit 27, or a control signal supplied from the sequencer 24, the driver set 28 generates, for example, various voltages or various control signals to be supplied to select gate lines SGD (refer to FIG. 3), word lines WL (refer to FIG. 3), a source line SL (refer to FIG. 3), bit lines BL (refer to FIG. 3), and the like in various operations such as a read operation and a write operation. The driver set 28 supplies the generated voltages or control signals to the sense amplifier module 100, the row decoder 29, the source line SL, and the like.

The row decoder 29 receives a row address from the address register, and decodes the received row address. Based on the result of the decoding, the row decoder 29 selects the block BLK (refer to FIG. 3) to be subjected to various operations such as a read operation and a write operation. The row decoder 29 can supply the voltage supplied from the driver set 28 to the selected block BLK.

The sense amplifier module 100 receives, for example, a column address from the address register, and performs transmission and reception operations of the data DAT between the memory controller 1 and the memory cell array 21 based on the column address. In addition, the sense amplifier module 100 can sense the data (threshold voltage) read from the memory cell array 21 based on an instruction related to a read operation, and can temporarily hold the read data. In addition, the sense amplifier module 100 can perform a logical operation based on the temporarily saved data. In addition, the sense amplifier module 100 transmits the data that has been read (the read data) DAT to the memory controller 1 via the input/output circuit 22. Furthermore, the sense amplifier module 100 receives write data DAT from the memory controller 1 via the input/output circuit 22 based on an instruction related to a write operation, and transmits the write data DAT to the memory cell array 21.

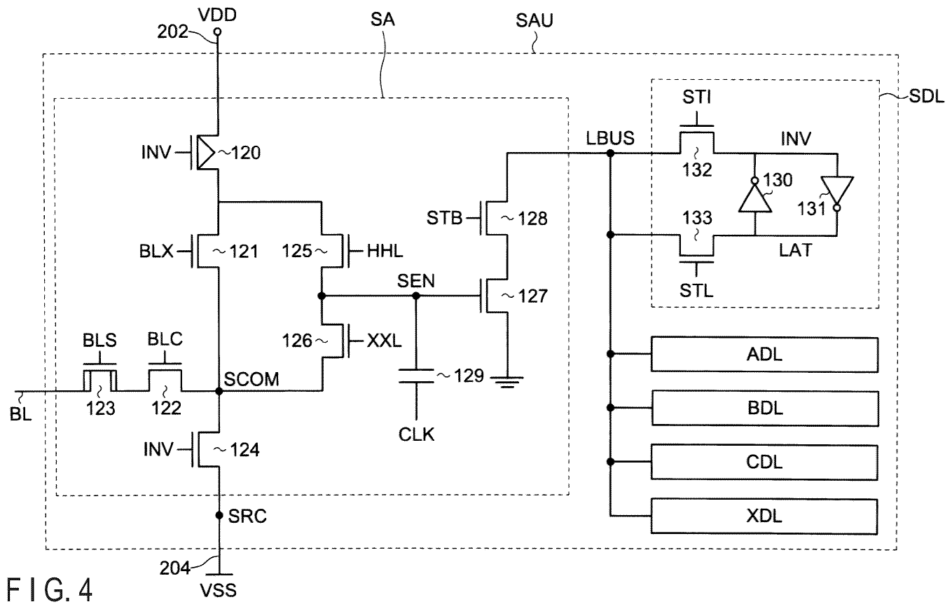

The sense amplifier module 100 includes, for example, a sense amplifier unit SAU (refer to FIG. 4) provided for each bit line BL (BL0 to BL (N-1), where (N-1) is a natural number of two or more, FIG. 3). The sense amplifier unit SAU is electrically connected to the bit line BL so as to be able to supply data to the bit line BL.

The input/output pad group 71 transmits the signal DQ <7:0> received from the memory controller 1 to the input/output circuit 22. The input/output pad group 71 transmits the signal DQ <7:0> received from the input/output circuit 22 to the memory controller 1.

The logic control pad group 72 transfers, to the logic control circuit 23, the chip enable signal CEn, the command latch enable signal CLE, the address latch enable signal ALE, the write enable signal WEn, and the read enable signal REn received from the memory controller 1. The logic control pad group 72 transfers the ready/busy signal R/Bn received from the ready/busy control circuit 26 to the memory controller 1.

### 1-4. Configuration of Memory Cell Array 21

Referring to FIG. 3, the configuration of the memory cell array 21 will be described. FIG. 3 is a circuit diagram of the block BLK included in the memory cell array 21 of the semiconductor memory device 2. Although a description will be given of the block BLK0 as an example, other blocks BLK1, 2, . . . , are also similar circuits. Note that the circuit diagram illustrated in FIG. 3 is an example, and does not limit the circuit diagram of the memory cell array 21 in the first embodiment. The configurations the same as or similar to those in FIG. 1 and FIG. 2 will be described when necessary, and a description of the configurations the same as or similar to those in FIG. 1 and FIG. 2 may be omitted.

The block BLK0 is connected to N bit lines BL (BL0, BL1, . . . , BL (N-1)). In addition, the block BLK0 is connected to the source line SL. A NAND string 116 is connected between each of the bit lines BL and the source line SL. The NAND string 116 includes, for example, eight memory cell transistors MT (MT0 to MT7), and selection transistors ST1 and ST2. The memory cell transistors MT each include a control gate and a charge storage layer, and hold data in a non-volatile manner. The memory cell transistors MT are connected in series between a source of the selection transistor ST1 and a drain of selection transistor ST2. The string units SU (SU0, SU1) are constituted by providing the NAND string 116 to each of the N bit lines BL. Note that, in FIG. 3, although the NAND string 116 includes, for example, the eight memory cell transistors MT, the number of memory cell transistors MT included in the NAND string 116 is not limited to eight. For example, the number of memory cell transistors MT may be i. For example, an integer i is a positive natural number, and the integer i may be larger than eight, or may be smaller than eight.

The selection transistor ST1 (corresponding to a lower layer select gate transistor, which will be described later) is connected to a select gate line SGD0. Gates of the selection transistors ST1 in each of the string units SU are each connected to the select gate line SGD (SGD0, SGD1, . . . ). Gates of the eight memory cell transistors MT (MT0 to MT7) are connected to the corresponding word lines WL (WL7 to WL0), respectively. In addition, a gate of the selection transistor ST2 in each of the string units SU is connected to a select gate line SGS. The gates of the selection transistors ST1 connected to the respective plurality of bit lines BL in the same string unit SU are connected to the common select gate line SGD. The gates of the memory cell transistors MT (MT0 to MT7) in the same string unit SU are connected to the common word lines WL (WL0 to WL7), respectively. The memory cell transistors MT (MT0 to MT7) connected to the same word line WL (WL0 to WL7) in the same string unit SU constitute a unit for a read operation and a write operation. For example, the memory cell transistor MT7 in each NAND string 116 included in the string unit SU corresponding to the select gate line SGD0 constitutes a memory cell group MG as a unit for a read operation and a write operation, and the read operation and the write operation are collectively performed on the memory cell group MG. For example, when the unit of data to be subjected to a read operation and a write operation is 16 kB, each memory cell group MG includes 217 memory cell transistors MT. In this case, 217 bit lines BL are provided.

### 1-5. Configuration of Sense Amplifier Unit SAU

Referring to FIG. 4, an example of the circuit configuration of the sense amplifier unit SAU will be described. FIG. 4 is a diagram illustrating an example of the circuit configuration of the sense amplifier unit SAU. Note that the circuit configuration of the sense amplifier unit SAU illustrated in FIG. 4 is an example, and the circuit configuration of the sense amplifier unit SAU of the semiconductor memory device 2 is not limited to the example illustrated in FIG. 4. The configurations the same as or similar to those in FIG. 1 to FIG. 3 will be described when necessary, and a description of the configurations the same as or similar to those in FIG. 1 to FIG. 3 may be omitted.

For example, the sense amplifier unit SAU can temporarily hold the data (threshold voltage) read out to the corresponding bit line BL. In addition, the sense amplifier unit SAU can perform a logical operation by using the temporarily saved data, and can temporarily hold the logically operated data. For example, the semiconductor memory device 2 can perform a read operation and a write operation by using the sense amplifier module 100 (the sense amplifier unit SAU).

As illustrated in FIG. 4, the sense amplifier unit SAU includes a sense amplifier unit SA, and latch circuits SDL, ADL, BDL, CDL, and XDL. The sense amplifier unit SA and the latch circuits SDL, ADL, BDL, CDL, and XDL are connected by a bus LBUS so as to be able to transmit and receive data to and from each other.

For example, the sense amplifier unit SA senses data read out to the corresponding bit line BL in a read operation to determine whether the read data is “0” or “1.” For example, the sense amplifier unit SA includes a p-channel MOS transistor 120, n-channel MOS transistors 121 to 128, and a capacitor 129.

One end of the transistor 120 is connected to a first power line 202, and a gate of the transistor 120 is connected to a node INV in the latch circuit SDL. One end of the transistor 121 is connected to the other end of the transistor 120, the other end of the transistor 121 is connected to a node COM, and a control signal BLX is input to a gate of the transistor 121. One end of the transistor 122 is connected to the node COM, and a control signal BLC is input to a gate of the transistor 122. The transistor 123 is a high-voltage MOS transistor, one end of the transistor 123 is connected to the other end of the transistor 122, the other end of the transistor 123 is connected to the corresponding bit line BL, and a control signal BLS is input to a gate of the transistor 123.

One end of the transistor 124 is connected to the node COM, the other end of the transistor 124 is connected to a node SRC, and a gate of the transistor 124 is connected to the node INV. One end of the transistor 125 is connected to the other end of the transistor 120, the other end of the transistor 125 is connected to a node SEN, and a control signal HLL is input to a gate of the transistor 125. One end of the transistor 126 is connected to the node SEN, the other end of the transistor 126 is connected to the node COM, and a control signal XXL is input to a gate of the transistor 126.

One end of the transistor 127 is grounded, and a gate of the transistor 127 is connected to the node SEN. One end of the transistor 128 is connected to the other end of the transistor 127, the other end of the transistor 128 is connected to the bus LBUS, and a control signal STB is input to a gate of the transistor 128. One end of the capacitor 129 is connected to the node SEN, and a clock CLK is input to the other end of the capacitor 129.

For example, the control signals BLX, BLC, BLS, HLL, XXL, and STB are generated by the sequencer 24. In addition, for example, a voltage VDD (first voltage), which is the internal power supply voltage of the semiconductor memory device 2, is supplied to the first power line 202 connected to the one end of the transistor 120. In addition, for example, the node SRC is electrically connected to a second power line 204, and a voltage VSS (second voltage) as a reference voltage of the semiconductor memory device 2 is supplied to the second power line. For example, the voltage VSS is the reference voltage that can define other voltage on the basis of the voltage VSS, the voltage VSS may be the reference voltage, may be 0 V, or may be the ground potential (earth potential).

The latch circuits SDL, ADL, BDL, CDL, and XDL temporarily hold the read data. For example, the latch circuit XDL is connected to the register 25, and is used for input and output of data between the sense amplifier unit SAU and the input/output circuit 22.

For example, the latch circuit SDL includes inverters 130 and 131, and n-channel MOS transistors 132 and 133. An input node of the inverter 130 is connected to a node LAT, and an output node of the inverter 130 is connected to the node INV. An input node of the inverter 131 is connected to the node INV, and an output node of the inverter 131 is connected to the node LAT. One end of the transistor 132 is connected to the node INV, the other end of the transistor 132 is connected to the bus LBUS, and a control signal STI is input to a gate of the transistor 132. One end of the transistor 133 is connected to the node LAT, the other end of the transistor 133 is connected to the bus LBUS, and a control signal STL is input to a gate of the transistor 133. For example, the data held in the node LAT corresponds to the data held in the latch circuit SDL, and the data held in the node INV corresponds to the inverted data of the data held in the node LAT. Since the circuit configurations of the latch circuits ADL, BDL, CDL, and XDL are similar to, for example, the circuit configuration of the latch circuit SDL, a description is omitted.

The timing at which each sense amplifier unit SAU in the sense amplifier module 100 determines the data read out to the bit line BL is based on the timing at which the control signal STB is asserted. For example, “the sequencer 24 asserts the control signal STB” corresponds to that the sequencer 24 changes the control signal STB from the “L”level to the “H”level.

Note that, in the sense amplifier unit SAU in the semiconductor memory device 2, the transistor 128 having the gate to which the control signal STB is input may be constituted by a p-channel MOS transistors. In this case, “the sequencer 24 asserts the control signal STB” corresponds to that the sequencer 24 changes the control signal STB from the “H”level to the “L”level.

In addition, the number of latch circuits included in the sense amplifier unit SAU can be set to an arbitrary number. For example, the number of latch circuits is designed based on the bit number of data held by one memory cell transistor MT. In addition, a plurality of bit lines BL may be connected to one sense amplifier unit SAU via a selector.

### 1-6. Circuit Configuration for Transmitting and Receiving Data toward Memory Cell Array 21 from Input/Output Circuit 22

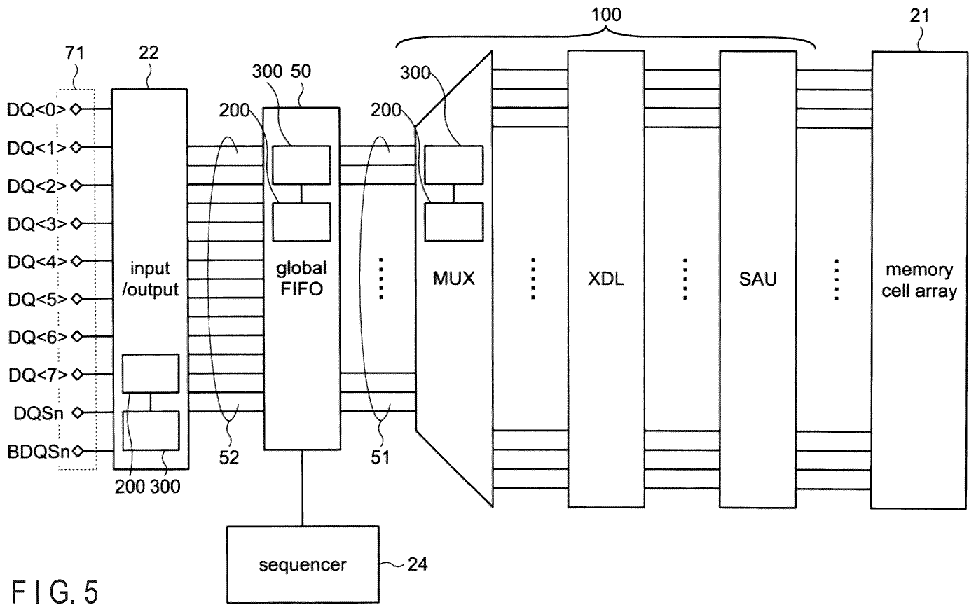

Referring to FIG. 5, the circuit configuration for transmitting and receiving data toward the memory cell array 21 from the input/output circuit 22 will be described. The configurations the same as or similar to those in FIG. 1 to FIG. 4 will be described when necessary, and a description of the configurations the same as or similar to those in FIG. 1 to FIG. 4 may be omitted.

In FIG. 5, paths between the input/output pad group 71 and the memory cell array 21 are schematically illustrated. For example, a path along which read data is transferred is a path from the memory cell array 21 to the input/output pad group 71, and a path along which write data is transferred is a path from the input/output pad group 71 to the memory cell array 21.

As described in “1-3. Configuration of Semiconductor Memory Device 2” or “1-5. Configuration of Sense Amplifier Unit SAU,” the sense amplifier module 100 includes the plurality of sense amplifier units SAU. In addition, each of the sense amplifier units SAU includes the sense amplifier unit SA and the latch circuit XDL. In addition, as illustrated in FIG. 5, the sense amplifier module 100 includes a multiplexer MUX electrically connected to a plurality of latch circuits XDL and a holding unit 50.

The multiplexer MUX is connected to the sequencer 24 and the holding unit 50 by a first data bus 51 consisting of 128 wires. The number of wires included in the first data bus 51 is not limited to 128. The number of wires included in the first data bus 51 is smaller than the number of wires connecting the plurality of latch circuits XDL and the multiplexer MUX.

The holding unit 50 is connected to the input/output circuit 22 by a second data bus 52 consisting of 16 signal lines. Note that the number of wires included in the second data bus 502 is not limited to 16. The holding unit 50 is a storage device (Global FIFO) that has a function of holding a plurality of pieces of data read from the memory cell array 21, and is configured to execute a so-called “FIFO” (First In First Out) operation.

The input/output circuit 22 is electrically connected to the input/output pad group 71. For example, the input/output pad group 71 includes ten pads. The signals DQ <0> to DQ <7>, the data strobe signal DQSn, and the complementary signal BDQSn are supplied to the ten pads corresponding to the respective signals, respectively.

In addition, the semiconductor memory device 2 includes a leakage current reduction circuit 300.

For example, at least one of the input/output circuit 22, the holding unit 50, and the multiplexer MUX includes an internal circuit 200 and the leakage current reduction circuit 300. As an example, in the semiconductor memory device 2 illustrated in FIG. 5, each of the input/output circuit 22, the holding unit 50, and the multiplexer MUX includes the internal circuit 200 and the leakage current reduction circuit 300. Although details will be described later, the leakage current reduction circuit 300 includes a plurality of logic circuits electrically connected to the internal circuit 200. For example, when an output signal of the internal circuit 200 maintains the “L” level or the “H” level, that is, when an input signal to one logic circuit of the plurality of logic circuits electrically connected to the internal circuit 200 maintains the “L” level or the “H” level, the leakage current reduction circuit 300 has a function of suppressing a leakage current of the plurality of logic circuits.

When distinguishing between leakage current reduction circuits 300, the leakage current reduction circuits 300 are illustrated as a leakage current reduction circuit 300A or a leakage current reduction circuit 300B. In addition, when distinguishing between internal circuits 200, the internal circuits 200 are illustrated as an internal circuit 200A or an internal circuit 200B.

Here, as an example, a method in which read data is transferred will be described.

For example, data read from the memory cell array 21 is transmitted from the sense amplifier unit SA to the latch circuit XDL, temporarily held, and thereafter transferred to the holding unit 50 via the multiplexer MUX. The multiplexer MUX sequentially transfers each piece of data transmitted from the plurality of latch circuits XDL to the holding unit 50 via the first data bus 51.

The holding unit 50 temporarily holds a plurality of pieces of data transferred from the multiplexer MUX, and transfers (outputs) the data to the input/output circuit 22 in the order of the data that is input first. The data transferred from the holding unit 50 to the input/output circuit 22 is temporarily held inside the input/output circuit 22, and is thereafter output as the signal DQ <7:0> to the outside from the input/output pad group 71.

For example, the sequencer 24 that has received a read request from the logic control circuit 23 controls the transfer of data from the holding unit 50 to the input/output circuit 22. When the semiconductor memory device 2 receives, from the host 4, a read request for reading data including successive pieces of “L” level data, and the data including the successive pieces of “L” level data is input to the leakage current reduction circuit 300, the sequencer 24 controls the leakage current reduction circuit 300 based on the request, so as to suppress the leakage current of the leakage current reduction circuit 300.

### 1-7. Leakage Current Reduction Circuit 300A

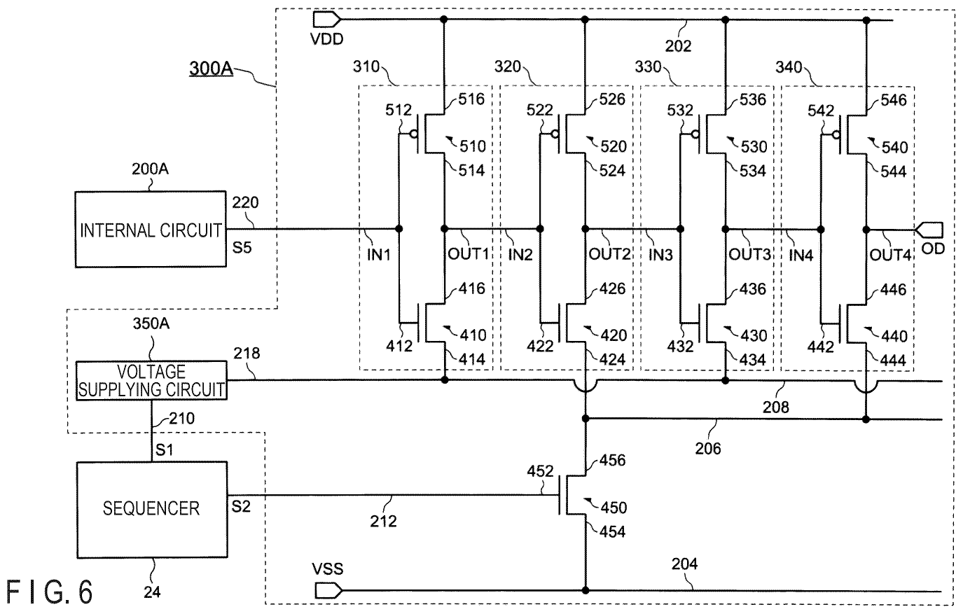

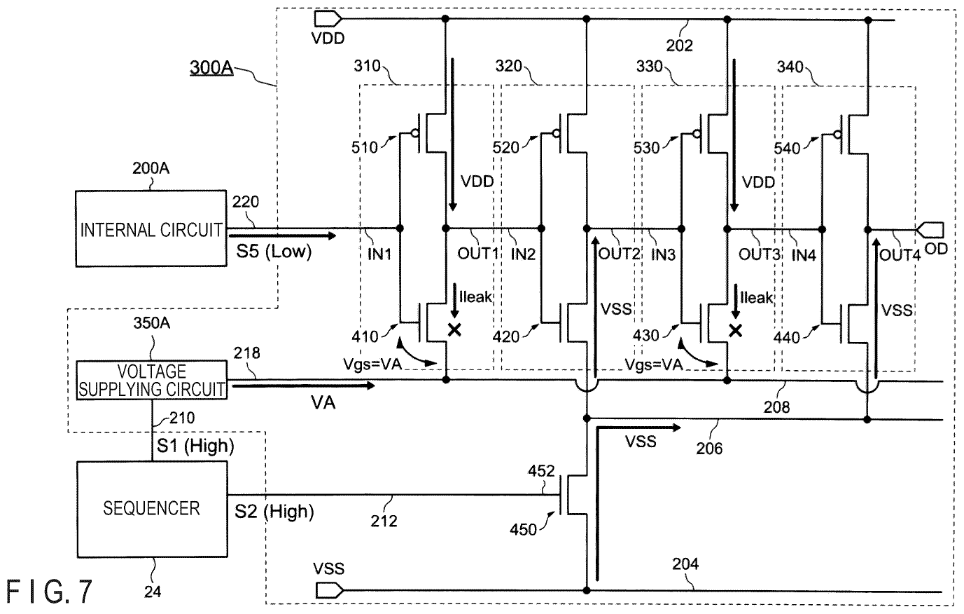

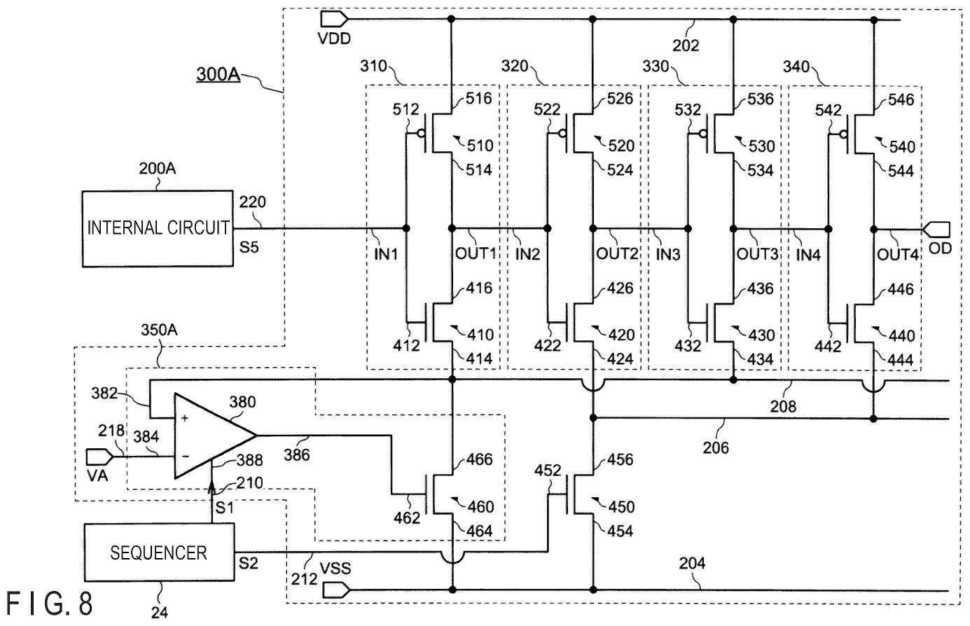

Referring to FIG. 6 to FIG. 8, the leakage current reduction circuit 300A will be described. FIG. 6 is a circuit diagram illustrating the configuration of the leakage current reduction circuit 300A. FIG. 7 is a diagram for describing an example of the operation of the leakage current reduction circuit 300A illustrated in FIG. 6. FIG. 8 is a circuit diagram illustrating the specific configuration of a voltage supplying circuit 350A included in the leakage current reduction circuit 300A.

### 1-7-1. Configuration of Leakage Current Reduction Circuit 300A

Referring to FIG. 6, the configuration of the leakage current reduction circuit 300A will be described. The leakage current reduction circuit 300A includes a plurality of logic circuits (logic circuits 310, 320, 330, and 340), a voltage supplying circuit 350A, and a transistor 450 (first transistor). The number of the plurality of logic circuits illustrated in FIG. 6 is an example, and the number of the plurality of logic circuits is not limited to the configuration illustrated in FIG. 6. For example, logic circuits are illustrated with the number of stages according to the number of electrically connected logic circuits. For example, one logic circuit is illustrated as one stage of logic circuit, and a circuit in which two logic circuits are electrically connected is illustrated as two stages of logic circuits. Therefore, the plurality of logic circuits illustrated is FIG. 6 are four stages of logic circuits. The configurations the same as or similar to those in FIG. 1 to FIG. 5 will be described when necessary, and a description of the configurations the same as or similar to those in FIG. 1 to FIG. 5 may be omitted.

For example, each of the logic circuits 310, 320, 330, and 340 is an inverter (NOT circuit). Each of the logic circuits 310, 320, 330, and 340 may be a NAND circuit, or may be a NOR circuit. In addition, each of the logic circuits 310, 320, 330, and 340 may be any circuit of an inverter, a NAND circuit, or a NOR circuit.

The logic circuit 310 (first logic circuit) includes a transistor 410 and a transistor 510. The transistor 410 includes a gate electrode 412, a first electrode 414, and a second electrode 416. The transistor 510 includes a gate electrode 512, a first electrode 514, and a second electrode 516. The gate electrode 412, the gate electrode 512, and an input terminal IN1 are electrically connected, the second electrode 416, the first electrode 514, and an output terminal OUT1 are electrically connected, the first electrode 414 is electrically connected to a second electrode 208, and the second electrode 516 is electrically connected to the first power line 202. In addition, the input terminal IN1 is electrically connected to the internal circuit 200A via a wire 220. The logic circuit 310 is controlled by a control signal S5 supplied to the input terminal IN1. When the “L” level is supplied to the control signal S5, the transistor 510 is turned ON, the transistor 410 is turned OFF, and the logic circuit 310 outputs the voltage VDD to the output terminal OUT1. When the “H” level is supplied to the control signal S5, the transistor 410 is turned ON, the transistor 510 is turned OFF, and the logic circuit 310 outputs, to the output terminal OUT1, a voltage VA (refer to FIG. 7 and the like) supplied to the second electrode 208.

The logic circuits 320, 330, and 340 have configurations similar to the configuration of the logic circuit 310.

The logic circuit 320 (second logic circuit) includes a transistor 420 and a transistor 520. The transistor 420 includes a gate electrode 422, a first electrode 424, and a second electrode 426. The transistor 520 includes a gate electrode 522, a first electrode 524, and a second electrode 526. The gate electrode 422, the gate electrode 522, and an input terminal IN2 are electrically connected, the second electrode 426, the first electrode 524, and an output terminal OUT2 are electrically connected, the first electrode 424 is electrically connected to a first electrode 206, and the second electrode 526 is electrically connected to the first power line 202. The first electrode 206 is provided separately from the second electrode 208. In addition, the input terminal IN2 is electrically connected to the output terminal OUT1. The logic circuit 320 is controlled by a signal (voltage, potential) supplied to the input terminal IN2 (the output terminal OUT1). When the “L” level is supplied to the signal, the transistor 520 is turned ON, the transistor 420 is turned OFF, and the logic circuit 320 outputs the voltage VDD to the output terminal OUT2. When the “H” level is supplied to the signal, the transistor 420 is turned ON, the transistor 520 is turned OFF, and the logic circuit 320 outputs, to the output terminal OUT2, the voltage VA (refer to FIG. 7 and the like) supplied to the second electrode 208.

The logic circuit 330 includes a transistor 430 and a transistor 530. The transistor 430 includes a gate electrode 432, a first electrode 434, and a second electrode 436. The transistor 530 includes a gate electrode 532, a first electrode 534, and a second electrode 536. The gate electrode 432, the gate electrode 532, and an input terminal IN3 are electrically connected, the second electrode 436, the first electrode 534, and an output terminal OUT3 are electrically connected, the first electrode 434 is electrically connected to the second electrode 208, and the second electrode 536 is electrically connected to the first power line 202. In addition, the input terminal IN3 is electrically connected to the output terminal OUT2. The logic circuit 330 is controlled by a signal (voltage, potential) supplied to the input terminal IN3 (the output OUT2). When the “L” level is supplied to the signal, the transistor 530 is turned ON, the transistor 430 is turned OFF, and the logic circuit 330 outputs the voltage VDD to the output terminal OUT3. When the “H” level is supplied to the signal, the transistor 430 is turned ON, the transistor 530 is turned OFF, and the logic circuit 330 outputs, to the output terminal OUT3, the voltage VA (refer to FIG. 7 and the like) supplied to the second electrode 208.

The logic circuit 340 includes a transistor 440 and a transistor 540. The transistor 440 includes a gate electrode 442, a first electrode 444, and a second electrode 446. The transistor 540 includes a gate electrode 542, a first electrode 544, and a second electrode 546. The gate electrode 442, the gate electrode 542, and an input terminal IN4 are electrically connected, the second electrode 446, the first electrode 544, and an output terminal OUT4 are electrically connected, the first electrode 444 is electrically connected to the first electrode 206, and the second electrode 546 is electrically connected to the first power line 202. In addition, the input terminal IN4 is electrically connected to the output terminal OUT3, and the output terminal OUT4 is electrically connected to an arbitrary circuit in each circuit. The logic circuit 340 is controlled by a signal (voltage, potential) supplied to the input terminal IN4 (the output OUT2). When the “L” level is supplied to the signal, the transistor 540 is turned ON, the transistor 440 is turned OFF, and the logic circuit 340 outputs the voltage VDD to the output terminal OUT4. When the “H” level is supplied to the signal, the transistor 440 is turned ON, the transistor 540 is turned OFF, and the logic circuit 340 outputs, to the output terminal OUT4, the voltage VA (refer to FIG. 7 and the like) supplied to the second electrode 208.

The voltage supplying circuit 350A is electrically connected to the second electrode 208 via a wire 218, and is electrically connects to the sequencer 24 via a wire 210. The voltage supplying circuit 350A is controlled by a control signal S1 (first control signal) supplied to the wire 210. For example, when the “L” level is supplied to the control signal S1, the voltage supplying circuit 350A is turned ON, and the voltage supplying circuit 350A outputs the voltage VA to the wire 218 and the second electrode 208. When the “H” level is supplied to the control signal S1, the voltage supplying circuit 350A is turned OFF, and the voltage supplying circuit 350A does not output the voltage VA to the wire 218 and the second electrode 208. The voltage supplying circuit 350A generates the voltage VA. The voltage VA is a voltage at which a potential difference Vgs (a gate-source voltage) between the gate electrode and the first electrode of each transistor becomes smaller than 0 V when each of the transistors 410, 420, 430, and 440 is in an OFF state. For example, the voltage VA is smaller than the voltage VDD (first voltage) and is larger than the voltage VSS (second voltage). For example, although the voltage VA is 50 mV, the voltage VA is not limited to 50 mV. The voltage VA can be set to any value according to the specifications and applications of the semiconductor memory device 2.

The transistor 450 includes a gate electrode 452, a first electrode 454, and a second electrode 456. The gate electrode 452 is electrically connected to the sequencer 24 via a wire 212, and the first electrode 454 is electrically connected to the second power line 204, and the second electrode 456 is electrically connected to the first electrode 206. The transistor 450 is controlled by a control signal S2 (second control signal) supplied to the wire 212. For example, when the “H” level is supplied to the control signal S2, the transistor 450 is turned ON, and the transistor 450 outputs the voltage VSS to the first electrode 206. When the “L” level is supplied to the control signal S2, the transistor 450 is turned OFF, and the transistor 450 does not output the voltage VSS to the first electrode 206.

The internal circuit 200A includes a plurality of logic circuits. The plurality of logic circuits include a combinational circuit or a sequential circuit. For example, the internal circuit 200A outputs the control signal S5 to the wire 220. The control signal S5 is an output signal of the internal circuit 200A. According to the signal input to the internal circuit 200A, the internal circuit 200A may output the “L” level control signal S5, may output the “H” level control signal S5, may output the control signal S5 that includes the “L” level and the “H” level, and that probabilistically includes more “L” levels than “H” levels, or may output the control signal S5 that includes the “L” level and the “H” level, and that probabilistically includes more “H” levels than “L” levels.

In the leakage current reduction circuit 300A, the odd-numbered logic circuits (310 and 330) are electrically connected to the second electrode 208, and the even-numbered logic circuits (320 and 230) are electrically connected to the first electrode 206 and the transistor 450. In addition, as described in “1-5. Configuration of Sense Amplifier Unit SAU,” the voltage VDD is supplied to the first power line 202. The voltage VSS is supplied to the second power line 204.

The transistors 410, 420, 430, 440, and 450 are n-channel MOS transistors, and the transistors 510, 520, 530, and 540 are p-channel MOS transistors.

It is assumed that a conduction state of a transistor in the semiconductor memory device 2 indicates a state where a first electrode (for example, a source electrode) and a second electrode (for example, a drain electrode) of a transistor are electrically connected, and the transistor is turned ON, and a non-conduction state of the transistor in the semiconductor memory device 2 indicates a state where the first electrode (for example, the source electrode) and the second electrode (for example, the drain electrode) of the transistor are not electrically connected, and the transistor is turned OFF. Note that, in each transistor, the source electrode and the drain electrode may be interchanged according to the voltage or potential supplied to each electrode.

### 1-7-2. Example of Operation Method of Leakage Current Reduction Circuit 300A

Referring to FIG. 7, an example of the operation method of the leakage current reduction circuit 300A will be described. In order to make the figure easier to read, the numerals of electrodes of each transistor and the like are omitted in FIG. 7. The example of the operation method illustrated in FIG. 7 includes that the internal circuit 200A supplies the “L” level control signal S5 to the wire 220. The configurations the same as or similar to those in FIG. 1 to FIG. 6 will be described when necessary, and a description of the configurations the same as or similar to those in FIG. 1 to FIG. 6 may be omitted.

For example, the semiconductor memory device 2 receives, from the host 4, a read request for reading data including successive pieces of “L” level data, and the sequencer 24 receives the read request from the logic control circuit 23. Based on the request, the sequencer 24 supplies the “H” level control signal S1 to the voltage supplying circuit 350A via the wire 210. In addition, based on the request, the sequencer 24 supplies the High level (“H” level) control signal S2 to the gate electrode 452 of the transistor 450 via the wire 212.

When the “H” level control signal S1 is received, the voltage supplying circuit 350A generates the voltage VA, and supplies the voltage VA to the second electrode 208 via the wire 218. When the “H” level control signal S2 is received, the transistor 450 is turned ON, and supplies the voltage VSS to the first electrode 206. The voltage VDD supplied to the first power line 202 is supplied to the transistors 510, 520, 530, and 540.

When the “L” level (for example, the voltage VSS or 0 V) control signal S5 is supplied to the first stage logic circuit 310, the transistor 510 is turned ON, and the logic circuit 310 outputs the voltage VDD to the output terminal OUT1 (the input terminal IN2). At this time, the “L” level control signal S5 is being supplied to the gate electrode 412 of the transistor 410, and the voltage VA is being supplied to the first electrode 414 of the transistor 410. As a result, the potential difference Vgs becomes the difference between the “L” level and the voltage VA, and is smaller than 0 V. Therefore, as illustrated in FIG. 7, a leakage current Ileak flowing through the transistor 410 is suppressed. Here, a symbol “x” illustrated in FIG. 7 means that the leakage current flowing between the second electrode 416 and the first electrode 414 of the transistor 410 is suppressed.

When the voltage VDD is supplied to the second stage logic circuit 320, the transistor 420 is turned ON, and the logic circuit 320 outputs the voltage VSS to the output terminal OUT2 (the input terminal IN3). At this time, the voltage VDD is supplied to the gate electrode 522 of the transistor 520, and the transistor 520 is in the OFF state.

When the voltage VSS is supplied to the third stage logic circuit 330, the transistor 530 is turned ON, and the logic circuit 330 outputs the voltage VDD to the output terminal OUT3 (the input terminal IN4). At this time, the voltage VSS is being supplied to the gate electrode 432 of the transistor 430, and the voltage VA is being supplied to the first electrode 434 of the transistor 430. As a result, similar to the potential difference Vgs of the transistor 410 in the first stage logic circuit 330, the potential difference Vgs of the transistor 430 in the third stage logic circuit 330 becomes the difference between the voltage VSS and the voltage VA, and is smaller than 0 V. Therefore, as illustrated in FIG. 7, the leakage current Ileak flowing through the transistor 430 is suppressed. Here, a symbol “x” illustrated in FIG. 7 means that the leakage current flowing between the second electrode 436 and the first electrode 434 of the transistor 430 is suppressed.

When the voltage VDD is supplied to the fourth stage logic circuit 340, the transistor 440 is turned ON, and the logic circuit 340 outputs the voltage VSS to the output terminal OUT4. At this time, the voltage VDD is supplied to the gate electrode 542 of the transistor 540, and the transistor 540 is in an OFF state. In addition, a control signal OD is a signal including the voltage VSS.

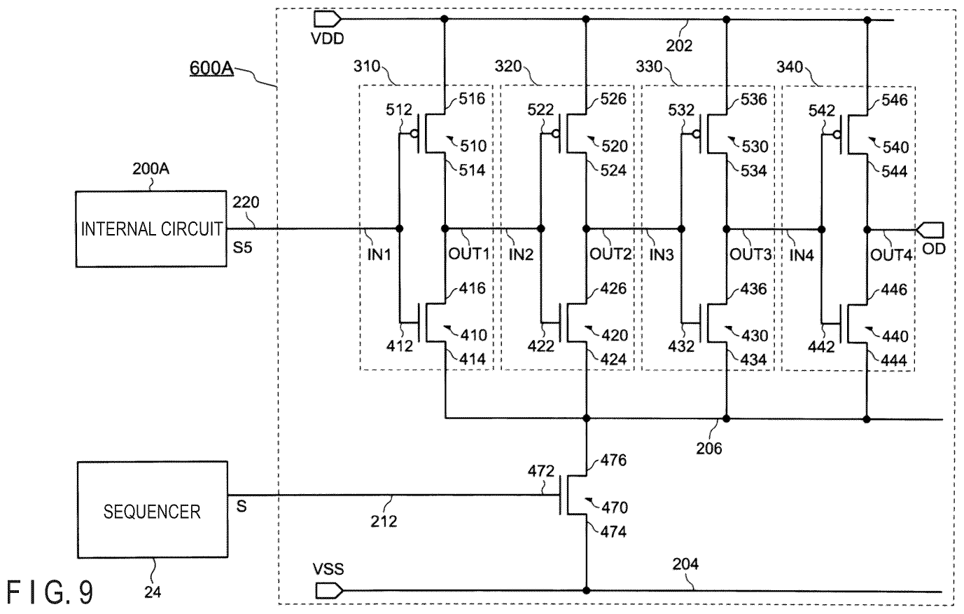

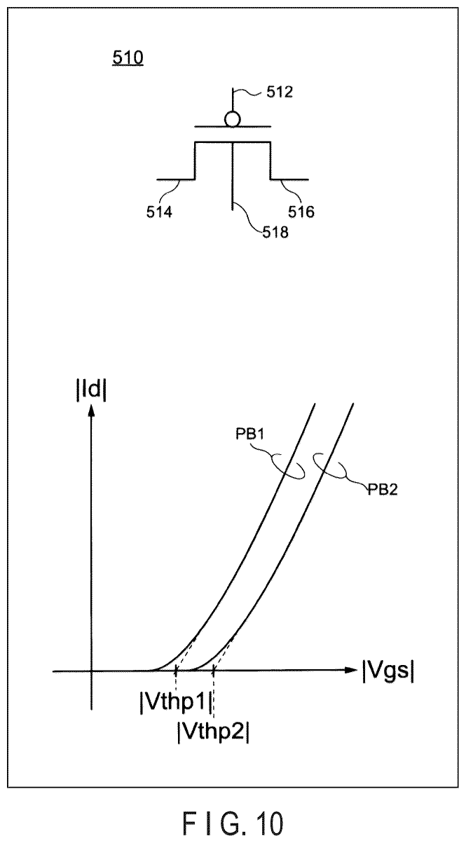

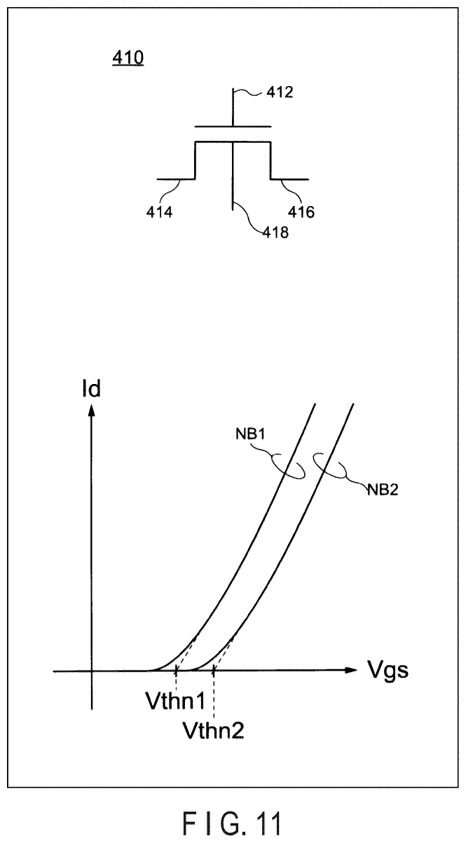

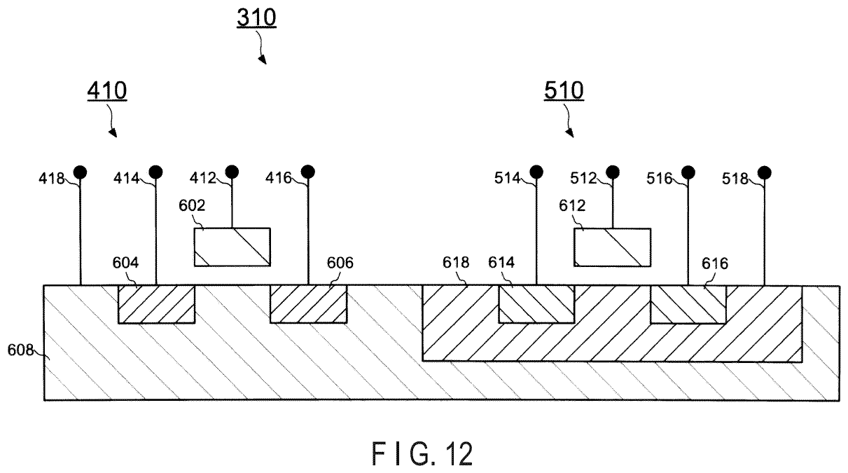

Here, Referring to FIG. 9 to FIG. 12, a leakage current reduction circuit (hereinafter written as the circuit 600A) according to a comparison example will be described. FIG. 9 is a circuit diagram illustrating an example of the configuration of the circuit 600A. FIG. 10 is a diagram for describing examples of an n-channel MOS transistor and the electrical characteristics of the n-channel MOS transistor. FIG. 11 is a diagram for describing examples of a p-channel MOS transistor and the electrical characteristics of the p-channel MOS transistor. FIG. 12 is a schematic diagram illustrating examples of the structures of the n-channel MOS transistor and the p-channel MOS transistor. Note that, in describing the circuit 600A, when the circuit 600A has a configuration similar to the configuration of the leakage current reduction circuit 300A, the circuit 600A will be described by using the components having the same numerals as those of the leakage current reduction circuit 300A.

As illustrated in FIG. 9, all of the first electrodes 414, 424, 434, and 444 of the logic circuits 310, 320, 330, and 340, respectively, in the circuit 600A are connected to the first electrode 206, and the first electrode 206 is electrically connected to the second power line 204 via an n-channel MOS transistor 470.

The circuit 600A can take at least a standby state and an active state. For example, the standby state is a state where, in the semiconductor memory device 2, although the internal power supply voltage (voltage VDD) is supplied, the circuit 600A is not used. At this time, a signal of the circuit 600A does not affect the next stage circuit. In addition, the active state is a state where the semiconductor memory device 2 is operable. At this time, the circuit 600A outputs a signal according to a signal supplied from the internal circuit 200A.

First, a description will be given of the suppression of a leakage current flowing through the circuit 600A when the circuit 600A is in the standby state. For example, when the circuit 600A is in the standby state, since the n-channel MOS transistor 470 is turned OFF, the n-channel MOS transistor 470 interrupts current paths of the logic circuits 310, 320, 330, and 340. For example, the n-channel MOS transistor 470 in the circuit 600A may be called a foot switch. By providing the foot switch in the circuit 600A, it is possible to suppress the leakage current in the standby state of the circuit 600A.

Note that, in the active state of the circuit 600A, when the on-resistance of the n-channel MOS transistor 470 (foot switch) is large, the voltage drop in the n-channel MOS transistor 470 becomes large, and the potential of the first electrode 206 rises above the voltage VSS. In this case, the operating speed of the logic circuits 310, 320, 330, and 340 is decreased. In order to ensure the operational performance of the circuit 600A in the active state, it is necessary to make the on-resistance of the n-channel MOS transistor 470 (foot switch) sufficiently small. Therefore, in the circuit 600A, the size of the n-channel MOS transistor 470 is made sufficiently large. Specifically, for example, the gate electrode 472 of the n-channel MOS transistor 470 is provided with a sufficient gate width. Accordingly, generally, when the circuit 600A is provided with the n-channel MOS transistor 470 as the foot switch, the area of the entire circuit 600A is increased.

On the other hand, the foot switch suppresses a leakage current in the standby state, and does not contribute to suppressing the leakage current in a case where the entire circuit 600A is in the active state.

Next, a description will be given of the suppression of the leakage current flowing through the circuit 600A in the case where the circuit 600A is in the active state. Generally, in an n-channel MOS transistor and a p-channel MOS transistor, a threshold voltage Vth of the MOS transistor is changed when a bias is applied to a substrate electrode. That is, the threshold voltage of the MOS transistor is controllable by applying a bias to the substrate electrode of the MOS transistor.

As an example, taking the transistor 510 as an example, a description will be given of the suppression of a leakage current in the active state of the p-channel MOS transistor using a substrate bias effect. For example, the configuration of the MOS transistor 510 and the electrical characteristic of the MOS transistor 510 are illustrated in FIG. 10. For example, it is assumed that the first electrode 514 is a drain electrode, the second electrode 516 is a source electrode, and a third electrode 518 is a body electrode (substrate electrode). The MOS transistors 520, 530, and 540 also have similar electrical characteristics. Note that a description of the substrate electrode of each p-channel MOS transistor according to the first embodiment and a second embodiment to be described later is omitted.

A plot illustrated in FIG. 10 illustrates the relationship between a voltage |Vgs| (the absolute value of Vgs) supplied between the gate electrode 512 and the first electrode 514 of the MOS transistor 510, and a drain current |Ids| (the absolute value of Ids). The plot includes electrical characteristics PB1 in a case where a bias is not applied to the third electrode 518, and electrical characteristics PB2 in a case where a bias is applied to the third electrode 518.

As illustrated in FIG. 10, a threshold voltage |Vthp2| (the absolute value of Vthp2) in the case where the bias is applied to the third electrode 518 is larger than a threshold voltage |Vthp1| (the absolute value of Vthp1) in the case where the bias is not applied to the third electrode 518. That is, when the same voltage |Vgs| is applied, the drain current |Ids| in the electrical characteristic PB2 in the case where the bias is applied to the third electrode 518 is smaller than the drain current |Ids| of the electrical characteristics PB1 in the case where the bias is not applied to the third electrode 518. The leakage current of the MOS transistor 510 (and the MOS transistors 520, 530, and 540) is suppressed due to the substrate bias effect caused by applying the bias to the third electrode 518. By applying the substrate bias effect to the p-channel MOS transistor included in the circuit 600A, the leakage current at the time when the circuit 600A is in the active state can be suppressed.

Similarly, taking the MOS transistor 410 as an example, a description will be given of the suppression of a leakage current in the active state of the n-channel MOS transistor using the substrate bias effect. For example, the configuration of the MOS transistor 410 and the electrical characteristics of the MOS transistor 410 are illustrated in FIG. 11. For example, the first electrode 414 is a drain electrode, the second electrode 416 is a source electrode, and a third electrode 418 is a body electrode (substrate electrode). The MOS transistors 420, 430, and 440 also have similar electrical characteristics. Note that, similar to the p-channel MOS transistor, a description of the substrate electrode of each n-channel MOS transistor according to the first embodiment and the second embodiment to be described later is omitted.

The plot illustrated in FIG. 11 illustrates the relationship between the voltage Vgs supplied between the gate electrode 412 and the first electrode 414 of the MOS transistor 410, and the drain current Ids. The plot illustrated in FIG. 11 includes electrical characteristics NB1 in a case where a bias is not supplied to the third electrode 418, and electrical characteristics NB2 in a case where the bias is applied to the third electrode 418.

As illustrated in FIG. 11, a threshold voltage Vthn2 in the case where the bias is applied to the third electrode 418 is larger than a threshold voltage Vthn1 in the case where the bias is not applied to the third electrode 418. That is, when the same voltage Vgs is applied, the drain current Ids in the electrical characteristics NB2 in the case where the bias is applied to the third electrode 418 is smaller than the drain current Ids in the electrical characteristics NB1 in the case where the bias is not applied to the third electrode 418. The leakage current of the MOS transistor 410 (and the MOS transistors 420, 430, and 440) is suppressed due to the substrate bias effect caused by applying the bias to the third electrode 418. By applying the substrate bias effect to the n-channel MOS transistor included in the circuit 600A, the leakage current at the time when the circuit 600A is in the active state can further be suppressed.

On the other hand, in practice, it is difficult to apply a substrate bias effect to an n-channel MOS transistor. The FIG. 12 schematically illustrates a cross-sectional configuration of the logic circuit 310 (the MOS transistor 410 and the MOS transistor 510). Note that, in FIG. 12, the specific connection relationship between the MOS transistor 410 and the MOS transistor 510 in the logic circuit 310 is omitted.

For example, as illustrated in FIG. 12, the gate electrode 412, the first electrode 414, the second electrode 416, the third electrode 418, the gate electrode 512, the first electrode 514, the second electrode 516, and the 3rd electrode 518 are connected to the gate 602, an n-type diffusion layer 604, an n-type diffusion layer 606, a p-type substrate 608, a gate 612, a p-type diffusion layer 614, a p-type diffusion layer 616, and an n well 618, respectively.

As illustrated in FIG. 12, the MOS transistor 510 is formed in the n well 618 provided in the p-type substrate 608, and the MOS transistor 410 is formed in the p-type substrate 608. In addition, the n well 618 is provided in each p-channel MOS transistor corresponding to the circuit 600A, and the p-type substrate 608 is shared with circuits other than the circuit 600A.

The leakage current in the active state of the MOS transistor 510 is suppressed by applying a bias to the n well 618 via the third electrode 518. On the other hand, the leakage current in the active state of the MOS transistor 410 is suppressed by applying a bias to the p-type substrate 608 via the third electrode 418. However, as described above, the p-type substrate 608 is shared with circuits other than the circuit 600A. Since the voltage VSS is typically supplied to the p-type substrate 608, it is difficult in the circuit 600A to apply a bias to the p-type substrate 608 for the purpose of reducing the leakage current in the active state of the MOS transistor 410.

For example, circuits other than the circuit 600A may give priority to a high-speed operation by decreasing the threshold voltage of a transistor over suppressing the leakage current in the active state by increasing the threshold voltage of the transistor. Therefore, the circuit 600A may be unable to utilize the substrate bias effect, depending on the states of circuits other than the circuit 600A.

That is, in the circuit 600A, although the leakage current in the active state of the p-channel MOS transistor can be suppressed by adjusting the threshold voltage of the transistor utilizing the substrate bias effect, it is difficult to suppress the leakage current in the active state of the n-channel MOS transistor by adjusting the threshold voltage of the transistor by utilizing the board bias effect.

Therefore, in the circuit 600A, even if the threshold voltages of the transistors are adjusted by utilizing the substrate bias effect, it is difficult to suppress the leakage current of the entire circuit 600A in the active state.

On the other hand, in the leakage current reduction circuit 300A, as described above, the first electrodes 414 and 434 of the transistors 410 and 430 of the odd-numbered logic circuits 310 and 330 are connected to the second electrode 208 to which the voltage VA is supplied by the voltage supplying circuit 350A, and the first electrodes 424 and 444 of the transistors 420 and 440 of the even-numbered logic circuits 320 and 340 are connected to the first electrode 206 to which to the transistor 450 is connected and to which the voltage VSS is supplied. Accordingly, since the voltage VA is supplied, by the voltage supplying circuit 350, to the odd-numbered logic circuits 310 and 330 to which the “L” level, the voltage VSS, or 0 V is input, the potential difference Vgs between the transistors 410 and 430 of the odd-numbered logic circuits 310 and 330 can be made smaller than 0 V. As a result, the semiconductor memory device 2 can suppress the leakage current Ileak flowing through the leakage current reduction circuit 300 than the leakage current reduction circuit (the circuit 600A) according to the comparison example.

### 1-7-3. Configuration of Voltage Supplying Circuit 350A

Referring to FIG. 8, a description will be given of a specific configuration of the voltage supplying circuit 350A included in the leakage current reduction circuit 300A. The configurations the same as or similar to those in FIG. 1 to FIG. 7 will be described when necessary, and a description of the configurations the same as or similar to those in FIG. 1 to FIG. 7 may be omitted.

The voltage supplying circuit 350A includes an operation amplifier circuit 380 and a transistor 460.

The operation amplifier circuit 380 includes a first input terminal 382, a second input terminal 384, a third input terminal 388, and an output terminal 386. The first input terminal 382 is electrically connected to the second electrode 208, and the second input terminal 384 is electrically connected to the wire 218 to which the voltage VA is supplied, the third input terminal 388 is electrically connected to the sequencer 24 via the wire 210, and the output terminal 386 is electrically connected to a gate electrode 462 of the transistor 460. For example, the voltage VA is generated by the voltage generation circuit 27, and is supplied to the voltage supplying circuit 350. For example, the operation amplifier circuit 380 operates so that the voltage supplied to the second electrode 208 maintains the voltage VA.

The transistor 460 includes the gate electrode 462, a first electrode 464, and a second electrode 466. The first electrode 464 is electrically connected to the second power line 204, and the second electrode 466 is electrically connected to the first electrode 206. The transistor 460 is controlled by a signal (voltage, potential) supplied to the output terminal 386. For example, when the “H” level is supplied to the output terminal 386, the transistor 450 is turned ON, and the transistor 460 outputs the voltage VSS to the first electrode 206. When the “L” level is supplied to the output terminal 386, the transistor 450 is turned OFF, and the transistor 450 does not output the voltage VSS to the first electrode 206. The transistor 460 is an n-channel MOS transistor. Note that the transistors 450 and 460 also function as foot switches.

For example, the leakage current reduction circuit (the circuit 600A) according to the comparison example illustrated in FIG. 9 has the configuration in which the n-channel MOS transistor 470 controls the logic circuits 310, 320, 330, and 340. It is necessary to make the size (for example, the gate width of the gate electrode 472) of the n-channel MOS transistor 470 large in order to ensure the current driving capability for the logic circuits 310, 320, 330, and 340.

On the other hand, the leakage current reduction circuit 300A includes the configuration in which the odd-numbered logic circuits 310 and 330 connected to the transistor 460 functioning as the foot switch and the even-numbered logic circuits 320 and 340 connected to the transistor 450 functioning as the foot switch are separated, and each can be controlled. The size of the transistor 460 may be large enough to ensure the current driving force for the logic circuits 310 and 330, and the size of the transistor 450 may be large enough to ensure the current driving force for the logic circuits 320 and 340. Therefore, the size of the transistor 470 provided in the circuit 600A of the comparative example and the sum of the sizes of the transistors 460 and 450 provided in the leakage current reduction circuit 300A of the present embodiment can be made equivalent. Therefore, the difference between the circuit area of the circuit 600A and the circuit area of the leakage current reduction circuit 300 is substantially limited to an increased due to adding the operation amplifier circuit 380 included in the voltage supplying circuit 350A.

That is, the leakage current reduction circuit 300A includes the configuration in which the odd-numbered logic circuits 310 and 330 and the even-numbered logic circuits 320 and 340 are separated, and the even-numbered logic circuits and the odd-numbered logic circuits can be controlled by using mutually different foot switches (the transistors 460 and 450), and the configuration that can minimize the increase in the circuit area. In this manner, the semiconductor memory device 2 including the leakage current reduction circuit 300A is capable of suppressing the leakage current in the active state as well as suppressing the leakage current in the standby state, while minimizing the increase in the circuit area, compared with the leakage current reduction circuit (the circuit 600A) according to the comparison example.

Note that, as the leakage current reduction circuit 300A, the example has been illustrated in which the voltage VA supplied by the voltage supplying circuit 350A is supplied to the second electrode 208 connected to the logic circuits 310 and 330. In this case, as illustrated in FIG. 7, when the control signal S5 supplied to the first stage logic circuit 310 is the “L” level, the effect of suppressing the leakage current in the active state becomes high. Accordingly, it is preferable to apply the configuration of the leakage current reduction circuit 300A to a circuit in which the “L” level control signal is often supplied to the first stage logic circuit. On the other hand, even in a case where the signal can be at either the “L” level or the “H” level, when a configuration similar to the configuration of the leakage current reduction circuit 300A is applied to a plurality of places of the semiconductor memory device 2, the leakage current in the active state can be statistically suppressed in the entire semiconductor memory device 2. In addition, in a circuit in which the “H” level control signal is often supplied to the first stage logic circuit, by configuring the circuit so that the voltage VA supplied by the voltage supplying circuit 350A is supplied to the first electrode 206 connected to the logic circuits 320 and 340, based on the configuration of the leakage current reduction circuit 300A, the effect of suppressing the leakage current in the active state can be made high.

### 2. Second Embodiment

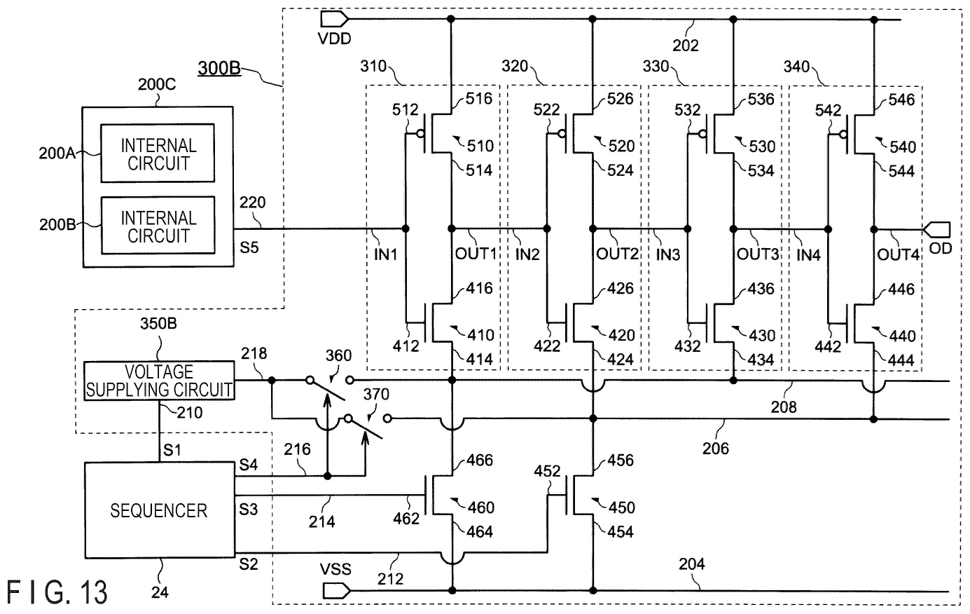

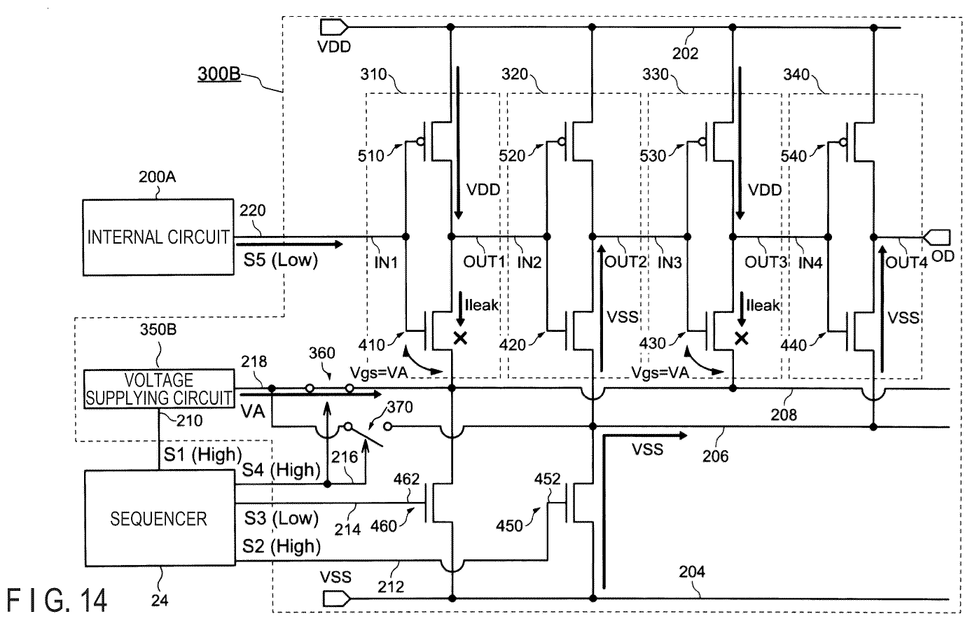

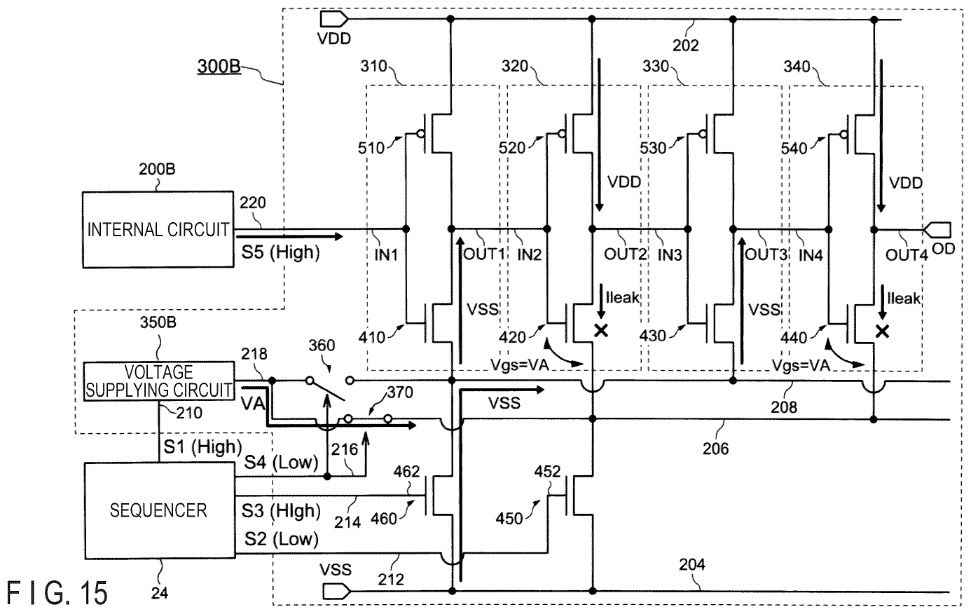

Referring to FIG. 13 to FIG. 15, the leakage current reduction circuit 300B according to a second embodiment will be described. FIG. 13 is a circuit diagram illustrating the configuration of the leakage current reduction circuit 300B. FIG. 14 and FIG. 15 are circuit diagrams for describing examples of the operation of the leakage current reduction circuit 300B illustrated in FIG. 13. The configurations the same as or similar to those in FIG. 1 to FIG. 12 will be described when necessary, and a description of the configurations the same as or similar to those in FIG. 1 to FIG. 12 may be omitted.

### 2-1. Configuration of Leakage Current Reduction Circuit 300B

Referring to FIG. 13, the configuration of the leakage current reduction circuit 300B will be described. The leakage current reduction circuit 300B includes Configuration 1 to Configuration 3 described below. Configuration 1 to Configuration 3 in the leakage current reduction circuit 300B are different from the configuration of the leakage current reduction circuit 300A according to the first embodiment. Configuration 1: the voltage supplying circuit 350B and the switches 360 and 370 are included. Configuration 2: the sequencer 24 is electrically connected to the transistor 450 via the wire 212, is electrically connected to the transistor 460 via the wire 214, is electrically connected to the switches 360 and 370 via the wire 216, and is electrically connected to the voltage supplying circuit 350B via the wire 210. Configuration 3: the configuration relevant to the voltage supplying circuit 350B, the switches 360 and 370, and the transistor 450, as well as the voltage supplying circuit 350B, the switches 360 and 370, and the transistor 460.

The voltage supplying circuit 350B is controlled by the control signal S1 supplied to the wire 210. For example, when the “H” level is supplied to the control signal S1, the voltage supplying circuit 350B is turned ON, and outputs the voltage VA to the wire 218. When the “L” level is supplied to the control signal S1, the voltage supplying circuit 350B is turned OFF, and the voltage supplying circuit 350B does not output the voltage VA to the wire 218. The voltage supplying circuit 350B generates the voltage VA.

The gate electrode 462 of the transistor 460 is electrically connected to the sequencer 24 via the wire 214. The transistor 460 is controlled by a control signal S3 (third control signal) supplied to the wire 214. For example, when the “H” level is supplied to the control signal S3, the transistor 460 is turned ON, and the transistor 460 outputs the voltage VSS to the second electrode 208. When the “L” level is supplied to the control signal S3, the transistor 460 is turned OFF, and the transistor 460 does not output the voltage VSS to the second electrode 208.

The switch 360 is electrically connected between the voltage supplying circuit 350B and the second electrode 208. In addition, the switch 360 is electrically connected to the sequencer 24 via the wire 216. A control signal S4 (fourth control signal) is supplied to the wire 216 by the sequencer 24, and the switch 360 is controlled by the control signal S4. For example, when the “H” level is supplied to the control signal S4, the switch 360 is turned ON, and the switch 360 outputs, to the second electrode 208, the voltage VA supplied to the wire 218 from the voltage supplying circuit 350B. When the “L” level is supplied to the control signal S4, the switch 360 is turned OFF, and the switch 360 does not output the voltage VA to the second electrode 208.

The switch 370 is electrically connected between the voltage supplying circuit 350B and the first electrode 206. In addition, the switch 370 is electrically connected to the sequencer 24 via the wire 216. The control signal S4 is supplied to the wire 216 by the sequencer 24, and the switch 370 is controlled by the control signal S4. For example, when the “L” level is supplied to the control signal S4, the switch 370 is turned ON, and the switch 370 outputs, to the first electrode 206, the voltage VA supplied to the wire 218 from the voltage supplying circuit 350B. When the “H” level is supplied to the control signal S4, the switch 370 is turned OFF, and the switch 370 does not output the voltage VA to the first electrode 206.

An internal circuit 200C includes the internal circuit 200A and the internal circuit 200B.

Similar to the leakage current reduction circuit 300A according to the first embodiment, the internal circuit 200A supplies the “L” level control signal S5 to the wire 220. In addition, the internal circuit 200B supplies the “H” level control signal S5 to the wire 220. For example, a control signal may be supplied to the internal circuit 200C from the sequencer 24, and the internal circuit 200C may select the internal circuit 200A or the internal circuit 200B. For example, based on the request, the sequencer 24 supplies the “H” level control signal S1 to the voltage supplying circuit 350 via the wire 210. In addition, since the sequencer 24 receives a request from the logic control circuit 23, the sequencer 24 recognizes in advance that the request includes successive “H” level signals, that the request includes successive “L” level signals, and that the request probabilistically includes the “L” level and the “H” level. Therefore, the sequencer 24 can control whether the internal circuit 200A or the internal circuit 200B is selected.

The configuration other than the above-described configuration including Configuration 1 to Configuration 3 is similar to the configuration of the leakage current reduction circuit 300A according to the first embodiment. The configurations and functions similar to those of the leakage current reduction circuit 300A will be described when necessary, and a description of the configurations and functions similar to those of the leakage current reduction circuit 300A may be omitted.

### 2-2. Example of Operation Method of Leakage Current Reduction Circuit 300B

Referring to FIG. 14, an example of the operation method of the leakage current reduction circuit 300B will be described. In order to make the figure easier to read, the numerals of electrodes of each transistor and the like are omitted in FIG. 14. An example of the operation method illustrated in FIG. 14 includes that the internal circuit 200A supplies the “L” level control signal S5 to the wire 220. The configurations the same as or similar to those in FIG. 1 to FIG. 13 will be described when necessary, and a description of the configurations the same as or similar to those in FIG. 1 to FIG. 13 may be omitted.

For example, the semiconductor memory device 2 receives, from the host 4, a read request for reading data including successive pieces of “L” level data, and the sequencer 24 receives the read request from the logic control circuit 23. Based on the request, the sequencer 24 supplies the “H” level control signal S1 to the voltage supplying circuit 350 via the wire 210, supplies the “H” level control signal S2 to the gate electrode 452 of the transistor 450 via the wire 212, supplies the “L” level control signal S3 to the gate electrode 462 of the transistor 460 via the wire 214, and supplies the “H” level control signal S4 to the switches 360 and 370 via the wire 216. In addition, for example, the sequencer 24 supplies the “H” level control signal to the internal circuit 200A.

When the switches 360 and 370 receive the “H” level control signal S4, the switch 360 is turned ON, and connects and electrically connects the wire 218 and the second electrode 208, and the switch 370 is turned OFF and interrupts the wire 218 and the first electrode 206. When the “H” level control signal S1 is received, the voltage supplying circuit 350B generates the voltage VA. In addition, when the “L” level control signal S3 is received, the transistor 460 is turned OFF, and interrupts the connection between the second power line 204 and the second electrode 208. Therefore, the voltage VA is supplied to the second electrode 208 via the wire 218 and the switch 360. When the “H” level control signal S2 is received, the transistor 450 is turned ON, and supplies the voltage VSS to the first electrode 206. For example, when the “H” level control signal is received, the internal circuit 200A supplies the “L” level control signal S5 to the first stage logic circuit 310. The voltage VDD supplied to the first power line 202 is supplied to the transistors 510, 520, 530, and 540.

The operation method of the first stage logic circuit 310 to the fourth stage logic circuit 340, in which the “L” level control signal S5 is supplied to the first stage logic circuit 310, and the logic circuit 340 outputs the voltage VSS to the output terminal OUT4, is similar to the operation method of the leakage current reduction circuit 300A described with reference to FIG. 7. Therefore, here, a description of the operation method of the leakage current reduction circuit 300B with reference to FIG. 14 will be omitted.

### 2-3. Example of Operation Method of Leakage Current Reduction Circuit 300B

Referring to FIG. 15, an example of the operation method of the leakage current reduction circuit 300B will be described. In order to make the figure easier to read, the numerals of electrodes of each transistor and the like are omitted in FIG. 15. An example of the operation method illustrated in FIG. 15 includes that the internal circuit 200B supplies the “H” level control signal S5 to the wire 220. The configurations the same as or similar to those in FIG. 1 to FIG. 14 will be described when necessary, and a description of the configurations the same as or similar to those in FIG. 1 to FIG. 14 may be omitted.

For example, the semiconductor memory device 2 receives, from the host 4, a read request for reading data including successive pieces of “H” level data, and the sequencer 24 receives the read request from the logic control circuit 23. Based on the request, the sequencer 24 supplies the “H” level control signal S1 to the voltage supplying circuit 350 via the wire 210, supplies the “L” level control signal S2 to the gate electrode 452 of the transistor 450 via the wire 212, supplies the “H” level control signal S3 to the gate electrode 462 of the transistor 460 via the wire 214, and supplies the “L” level control signal S4 to the switches 360 and 370 via the wire 216. In addition, for example, the sequencer 24 supplies the “L” level control signal to the internal circuit 200B.

When the switches 360 and 370 receive the “L” level control signal S4, the switch 370 is turned ON, and connects and electrically connects the wire 218 and the first electrode 206, and the switch 360 is turned OFF and interrupts the wire 218 and the second electrode 208. When the “H” level control signal S1 is received, the voltage supplying circuit 350B generates the voltage VA. In addition, when the “L” level control signal S2 is received, the transistor 450 is turned OFF, and interrupts the connection between the second power line 204 and the first electrode 206. Therefore, the voltage VA is supplied to the second electrode 208 via the wire 218 and the switch 360. When the “H” level control signal S2 is received, the transistor 460 is turned ON, and supplies the voltage VSS to the second electrode 208. For example, when an “L” level control signal is received, the internal circuit 200B supplies the “H” level control signal S5 to the first stage logic circuit 310. The voltage VDD supplied to the first power line 202 is supplied to the transistors 510, 520, 530, and 540.

When the “H” level (for example, the voltage VDD) control signal S5 is supplied to the first stage logic circuit 310, the transistor 410 is turned ON, and the logic circuit 310 outputs the voltage VSS to the output terminal OUT1 (the input terminal IN2). At this time, the “H” level control signal S5 is supplied to the gate electrode 522 of the transistor 510, and the transistor 520 is in the OFF state.

When the voltage VSS is supplied to the second stage logic circuit 320, the transistor 520 is turned ON, and the logic circuit 320 outputs the voltage VDD to the output terminal OUT2 (the input terminal IN3). The voltage VSS is supplied to the gate electrode 422 of the transistor 420, and the voltage VA is supplied to the first electrode 424 of the transistor 420. As a result, the potential difference Vgs becomes the difference between the voltage VSS and the voltage VA, and is smaller than 0 V. Therefore, as illustrated in FIG. 15, the leakage current Ileak flowing through the transistor 420 is suppressed. Here, a symbol “x” illustrated in FIG. 15 means that the leakage current flowing between the second electrode 426 and the first electrode 424 of the transistor 420 is suppressed.

When the voltage VDD is supplied to the third stage logic circuit 330, the transistor 430 is turned ON, and the logic circuit 330 outputs the voltage VSS to the output terminal OUT3 (the input terminal IN4). At this time, the voltage VDD is supplied to the gate electrode 532 of the transistor 530, and the transistor 530 is in an OFF state.

When the voltage VSS is supplied to the fourth stage logic circuit 340, the transistor 540 is turned ON, and the logic circuit 340 outputs the voltage VDD to the output terminal OUT4. At this time, the voltage VSS is supplied to the gate electrode 442 of the transistor 440, and the voltage VA is supplied to the first electrode 444 of the transistor 440. As a result, similar to the potential difference Vgs of the transistor 420 in the second stage logic circuit 320, the potential difference Vgs of the transistor 440 in the fourth stage logic circuit 340 becomes the difference between the voltage VSS and the voltage VA, and is smaller than 0 V. Therefore, as illustrated in FIG. 15, the leakage current Ileak flowing through the transistor 440 is suppressed. Here, a symbol “x” illustrated in FIG. 15 means that the leakage current flowing between the second electrode 446 and the first electrode 444 of the transistor 440 is suppressed. In addition, the control signal OD is the signal including the voltage VDD.

That is, similar to the leakage current reduction circuit 300A, the leakage current reduction circuit 300B includes the configuration in which the odd-numbered logic circuits 310 and 330 and the even-numbered logic circuits 320 and 340 are separated, and the even-numbered logic circuits and the odd-numbered logic circuits can be controlled by using mutually different foot switches (the transistors 460 and 450). In addition, the leakage current reduction circuit 300B can control supplying the voltage VA to the first electrode 206 and supplying the voltage VSS to the second electrode 208, and supplying the voltage VSS to the first electrode 206 and supplying the voltage VA to the second electrode 208, by using the control signals S1 to S4, the voltage supplying circuit 350B, the switches 360 and 370, and the transistors 450 and 460. As a result, since the semiconductor memory device 2 can control the foot switches (the transistors 460 and 450) according to the control signal S5 supplied to the leakage current reduction circuit 300B, the semiconductor memory device 2 is capable of suppressing the leakage current in the active state as well as suppressing the leakage current in the standby state, compared with the leakage current reduction circuit (the circuit 600A) according to the comparison example. In addition, since the voltage supplying circuit 350B can selectively supply the voltage VA to either the second electrode 208 connected to the logic circuits 310 and 330 or the first electrode 206 connected to the logic circuits 320 and 340, even when the “L” level control signal is supplied to the first stage logic circuit, and even when the “H” level control signal is supplied to the first stage logic circuit, the effect of suppressing the leakage current in the active state can be made high.

In each of the above-described embodiments, when the terms “the same” and “match” are used, “the same” and “match” may include cases where an error within a design range is included.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A semiconductor device, comprising:
a first power line to which a first voltage is supplied;
a second power line to which a second voltage lower than the first voltage is supplied;
a first logic circuit including a first electrode, and electrically connected to the first power line;
a second logic circuit including a second electrode provided separately from the first electrode, and electrically connected to the first power line and the first logic circuit;
a voltage supplying circuit configured to control, based on a first control signal, whether or not to supply a third voltage to the first electrode, the third voltage being lower than the first voltage and higher than the second voltage; and
a first transistor including a gate electrode to which a second control signal is input, and electrically connected between the second electrode and the second power line.

2. The semiconductor device of claim 1, further comprising a control circuit configured to output the first control signal and the second control signal.

3. The semiconductor device of claim 2, wherein when the second voltage is input to the first logic circuit, the control circuit is configured to:
control the voltage supplying circuit to supply a high-level voltage to the first control signal, and supply the third voltage to the first electrode; and
control the first transistor to supply a high-level voltage to the second control signal, and supply the second voltage to the second electrode.

4. The semiconductor device of claim 1, wherein the first transistor is an n-channel MOS transistor.

5. The semiconductor device of claim 4, wherein the voltage supplying circuit includes:
a second transistor including a gate electrode, and electrically connected between the second electrode and the second power line; and
an operation amplifier circuit including a first input terminal electrically connected to the second electrode, a second input terminal to which the third voltage is supplied, a third input terminal to which the first control signal is input, and an output terminal electrically connected to the gate electrode of the second transistor, and
the second transistor is an n-channel MOS transistor.

6. The semiconductor device of claim 2, wherein the control circuit outputs the first control signal to the voltage supplying circuit.

7. The semiconductor device of claim 2, wherein the control circuit outputs the second control signal to the gate electrode.

8. A semiconductor device, comprising:
a first power line to which a first voltage is supplied;
a second power line to which a second voltage lower than the first voltage is supplied;
a first logic circuit including a first electrode, and electrically connected to the first power line;
a second logic circuit including a second electrode provided separately from the first electrode, and electrically connected to the first power line and the first logic circuit;
a voltage supplying circuit configured to control, based on a first control signal, whether or not to supply a third voltage to the first electrode, the third voltage being lower than the first voltage and higher than the second voltage;
a first transistor including a gate electrode to which a second control signal is input, and electrically connected between the second electrode and the second power line;
a second transistor including a gate electrode to which a third control signal is input, and electrically connected between the first electrode and the second power line;
a first switch which is controlled by a fourth control signal, and which is electrically connected between the voltage supplying circuit and the first electrode; and
a second switch which is controlled by the fourth control signal, and which is electrically connected between the voltage supplying circuit and the second electrode.

9. The semiconductor device of claim 8, wherein the first transistor and the second transistor are n-channel MOS transistors.

10. The semiconductor device of claim 9, further comprising a control circuit configured to output the first control signal, the second control signal, the third control signal, and the fourth control signal.

11. The semiconductor device of claim 10, wherein when the second voltage is input to the first logic circuit, the control circuit is configured to control execution of:
supplying a high-level voltage to the fourth control signal, turning ON the second switch to electrically connect the voltage supplying circuit and the second electrode, and turning OFF the first switch to interrupt the voltage supplying circuit and the first electrode;
supplying a high-level voltage to the first control signal, and supplying the third voltage to the second electrode by the voltage supplying circuit;
supplying a low-level voltage to the third control signal, and turning OFF the second transistor to interrupt the second power line and the second electrode; and
supplying a high-level voltage to the second control signal, and turning ON the first transistor to electrically connect the second power line and the first electrode.

12. The semiconductor device of claim 10, wherein when the first voltage is input to the first logic circuit, the control circuit is configured to control execution of:
supplying a low-level voltage to the fourth control signal, turning ON the first switch to electrically connect the voltage supplying circuit and the first electrode, and turning OFF the second switch to interrupt the voltage supplying circuit and the second electrode;
supplying a high-level voltage to the first control signal, and supplying the third voltage to the first electrode by the voltage supplying circuit;
supplying a high-level voltage to the third control signal, and turning ON the second transistor to electrically connect the second power line and the second electrode; and
supplying a low-level voltage to the second control signal, and turning OFF the first transistor to interrupt the second power line and the first electrode.

13. The semiconductor device of claim 10, wherein the control circuit outputs the first control signal to the voltage supplying circuit.

14. The semiconductor device of claim 10, wherein the control circuit outputs the second control signal to the first transistor.

15. The semiconductor device of claim 10, wherein the control circuit outputs the third control signal to the second transistor.

16. A semiconductor device, comprising:
a first logic circuit including a first electrode, the first logic circuit being electrically connected to a first power line to which a first voltage is supplied;
a second logic circuit including a second electrode provided separately from the first electrode, the second logic circuit being electrically connected to the first power line and the first logic circuit;
a first transistor including a gate electrode to which a second control signal is input, the first transistor being electrically connected between the second electrode and a second power line to which a second voltage lower than the first voltage is supplied; and
a voltage supplying circuit configured to control, based on a first control signal, whether or not to supply a third voltage to the first electrode, the third voltage being lower than the first voltage and higher than the second voltage.

17. The semiconductor device of claim 16, further comprising a control circuit configured to output the first control signal and the second control signal.

18. The semiconductor device of claim 17, wherein when the second voltage is input to the first logic circuit, the control circuit is configured to:
control the voltage supplying circuit to supply a high-level voltage to the first control signal, and supply the third voltage to the first electrode; and
control the first transistor to supply a high-level voltage to the second control signal, and supply the second voltage to the second electrode.

19. The semiconductor device of claim 16, wherein the first transistor is an n-channel MOS transistor.

20. The semiconductor device of claim 16, wherein the voltage supplying circuit includes:
a second transistor including a gate electrode, and electrically connected between the second electrode and the second power line; and
an operation amplifier circuit including a first input terminal electrically connected to the second electrode, a second input terminal to which the third voltage is supplied, a third input terminal to which the first control signal is input, and an output terminal electrically connected to the gate electrode of the second transistor.
